(19) United States
(12) Patent Application Publication
(10) Pub. No.: US 2022/0365553 A1
(43) Pub. Date: Nov. 17, 2022

(54) MEASUREMENT APPARATUS AND MEASUREMENT METHOD

(71) Applicant: ADVANTEST CORPORATION, Tokyo (JP)

(72) Inventor: Kiyotaka ICHIYAMA, Saitama (JP)

(21) Appl. No.: 17/719,340

(22) Filed: Apr. 12, 2022

(30) Foreign Application Priority Data
May 11, 2021 (JP) 2021-080600

(51) Int. Cl. G06F 1/10; G06F 11/27

(52) U.S. Cl. CPC G06F 1/10; G06F 11/27

(57) ABSTRACT

A measurement apparatus comprising: a clock generator configured to generate a sampling clock having a longer sampling cycle than a symbol cycle in a pattern under test including a symbol with a predefined number of symbols; a sampler configured to sample, according to the sampling clock, the pattern under test that is repeatedly inputted; and a measuring section configured to measure a sampling result of the sampler according to the sampling clock of a time point corresponding to a symbol transition that becomes subject to jitter measurements in the pattern under test that is repeatedly inputted.

The contents of the following Japanese patent application(s) are incorporated herein by reference:

NO. 2021-080600 filed in JP on May 11, 2021

### BACKGROUND

### 1. Technical Field

The present invention relates to a measurement apparatus and a measurement method.

### 2. Related Art

In a test for a device under test having a communication function, a measurement apparatus measures jitters of signals under test fed by a device under test. For example, in a high-speed Ethernet (registered trademark) such as 200GAUI and 400GAUI, jitter measurements methods are defined by a standard. In this standard, the device under test outputs a PRBS13Q pattern, which is a kind of pseudo-random patterns, as a signal under test. The measurement apparatus is required to measure jitters of a symbol transition which corresponds to a certain pattern of a signal under test of PAM-4 (4 Pulse Amplitude Modulation) fed by the device under test during a sequence.

### BRIEF DESCRIPTION OF THE DRAWINGS

FIG. 1 shows one example of a configuration of a DUT 100 that feeds a pattern under test including a pseudo-random pattern.

FIG. 2 shows one example of a signal under test fed by a DUT 100.

FIG. 3 is a table that shows Gray code conversions performed by a mapping section 130.

FIG. 4 shows a relation between a symbol transition of a PAM-4 signal and a threshold level.

FIG. 5 shows one example of patterns of symbols that are subject to jitter measurements.

FIG. 6 shows a configuration of a measurement apparatus 600 according to the present embodiment.

FIG. 7 shows a configuration of a clock generator 620 according to the present embodiment.

FIG. 8 shows a configuration of a shifter 700 according to the present embodiment.

FIG. 9 shows a configuration of a sampler 640 according to the present embodiment.

FIG. 10 shows a configuration of a synchronization pattern producing section 650 according to the present embodiment.

FIG. 11 shows a configuration of a trigger producing section 660 according to the present embodiment.

FIG. 12 is a time point chart that shows one example of an operation of a synchronization pattern producing section 650 and a trigger producing section 660 according to the present embodiment.

FIG. 13 shows a configuration of threshold generator 670 according to the present embodiment.

FIG. 14 shows a configuration of a measuring section 680 according to the present embodiment.

FIG. 15 shows one example of an measurement method of EOJ (even-odd jitter).

FIG. 16 shows the first example of a method to identify a symbol transition used for measuring EOJs, from repeated patterns under test.

FIG. 17 shows the second example of a method to identify a symbol transition used for measuring EOJs, from repeated patterns under test.

FIG. 18 shows a configuration of a counter section 1410 according to the present embodiment.

FIG. 19 shows a configuration of a synchronization pattern generator 1900 according to the first variant of the present embodiment.

FIG. 20 shows a configuration of a trigger producing section 2000 according to the second variant of the present embodiment.

FIG. 21 shows an example of a computer 2200 in which a plurality of aspects of the present invention may be entirely or partially embodied.

### DESCRIPTION OF EXEMPLARY EMBODIMENTS

Hereinafter, the present invention will be described by way of embodiments of the invention, but the following embodiments are not intended to restrict the invention according to the claims. Moreover, not all combinations of features described in the embodiments are necessary to solutions of the invention.

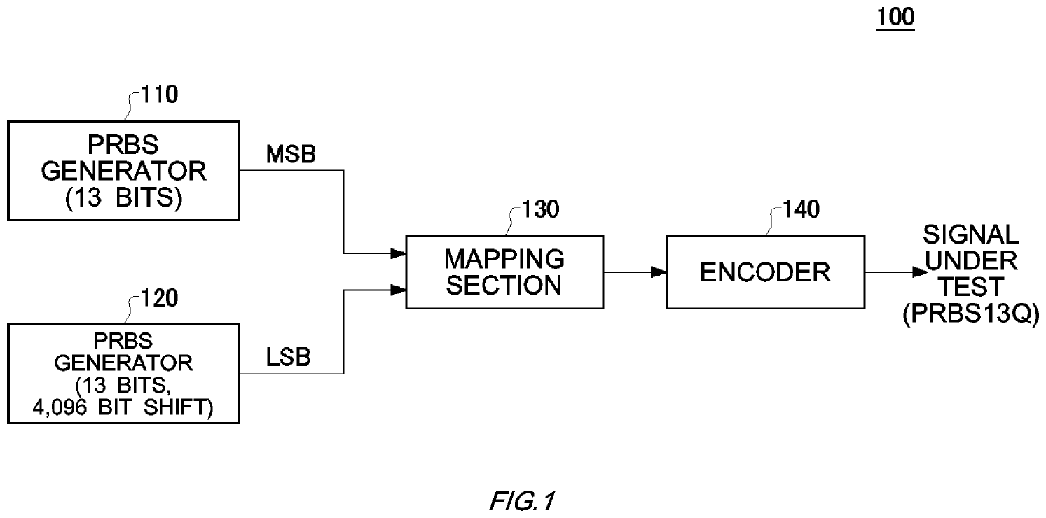

FIG. 1 shows one example of a configuration of a DUT 100 (a tested device 100) that feeds a pattern under test including a pseudo-random pattern. The DUT 100 in this figure, as one example, feeds a PRBS13Q used for jitter measurements of 200GAUI and 400GAUI, as a pattern under test. The DUT 100 comprises a PRBS generator 110, a PRBS generator 120, a mapping section 130, and an encoder 140.

The PRBS generator 110 generates a pseudo-random pattern for a most significant bit (MSB) in multi-value transmission data (four values of PAM-4 in the present example) fed by the DUT 100. In the example of this figure, the PRBS generator 110 is a pseudo-random pattern generator with a 13-bit pattern and repeatedly generates a pseudo-random pattern of 8,191 bits. The PRBS generator 110 outputs a pseudo-random pattern to a mapping section 130 bit by bit every symbol cycle according to a high frequency clock signal of, for example, 26.5625 GHz.

The PRBS generator 120 generates a pseudo-random pattern for a least significant bit (LSB) in multi-value transmission data (four values of PAM-4 in the present example) fed by the DUT 100. In the example of this figure, the PRBS generator 120 is a pseudo-random pattern generator of 13-bit patterns and repeatedly generates a pseudo-random pattern of 8,191 bits. Here, the PRBS generator 120 generates a pseudo-random pattern that is shifted by 4,096 bits from a pseudo-random pattern outputted by the PRBS generator 110. The PRBS generator 120, in a similar manner to the PRBS generator 110, outputs a pseudo-random pattern to the mapping section 130 bit by bit every symbol cycle.

The mapping section 130 connects to the PRBS generator 110 and the PRBS generator 120. The mapping section 130 receives multi-value transmission data including a most significant bit from the PRBS generator 110 and a least significant bit from the PRBS generator 120 so as to map on a symbol outputted by the DUT 100. In the example of this figure, the mapping section 130 maps on a symbol code by converting the transmission data into a Gray code.

An encoder 140 connects to the mapping section 130. The encoder 140 encodes a symbol code received from the mapping section 130 into a multi-value signal. In the example of this figure, the encoder 140 encodes a symbol code into a symbol of a PAM-4 signal having a signal level of four values. The encoder 140 feeds the encoded symbol of multi-value signal every symbol cycle. This allows the encoder 140 to repeatedly feed a pattern under test, which is, for example, a PRBS13Q.

In the above example, the DUT 100 repeatedly feeds a pattern under test of a PRBS13Q, which uses a PAM-4 signal as a symbol. Instead of this, the DUT 100 may repeatedly feed other patterns under test including a symbol with a predefined number of symbols.

In the above example, the DUT 100 has the PRBS generator 110 and the PRBS generator 120 built in and has a function to feed a pattern under test such as a PRBS13Q. Instead of this, when the DUT 100 does not have a PRBS generator 110 and a PRBS generator 120, a PRBS generator 110 and a PRBS generator 120 may be provided on the side of the measurement apparatus which measures jitters of the DUT 100 so that transmission data is supplied to the DUT 100.

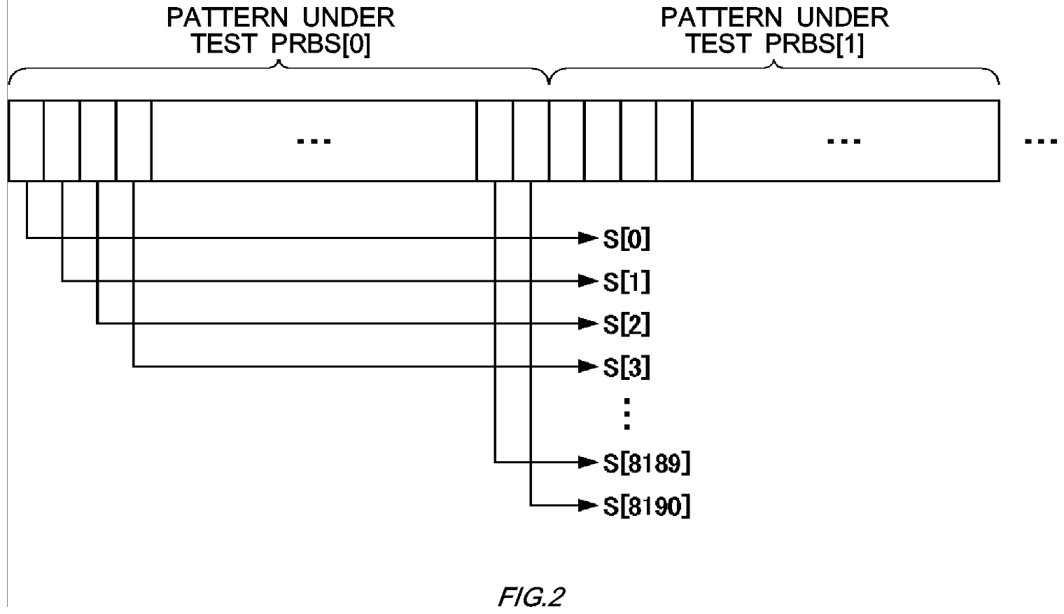

FIG. 2 shows one example of a signal under test fed by a DUT 100. The DUT 100 repeatedly feeds, as a signal under test, identical patterns under test including a symbol with a predefined number of symbols, symbol by symbol every symbol cycle. In the present example, repeatedly fed patterns under test of a PRBS13Q are shown as PRBS[0], PRBS[1], . . . in a chronological order. Each pattern under test of the PRBS13Q is consisting of 8,191 symbols shown as S [0], S [1], . . . S [8190] in a chronological order.

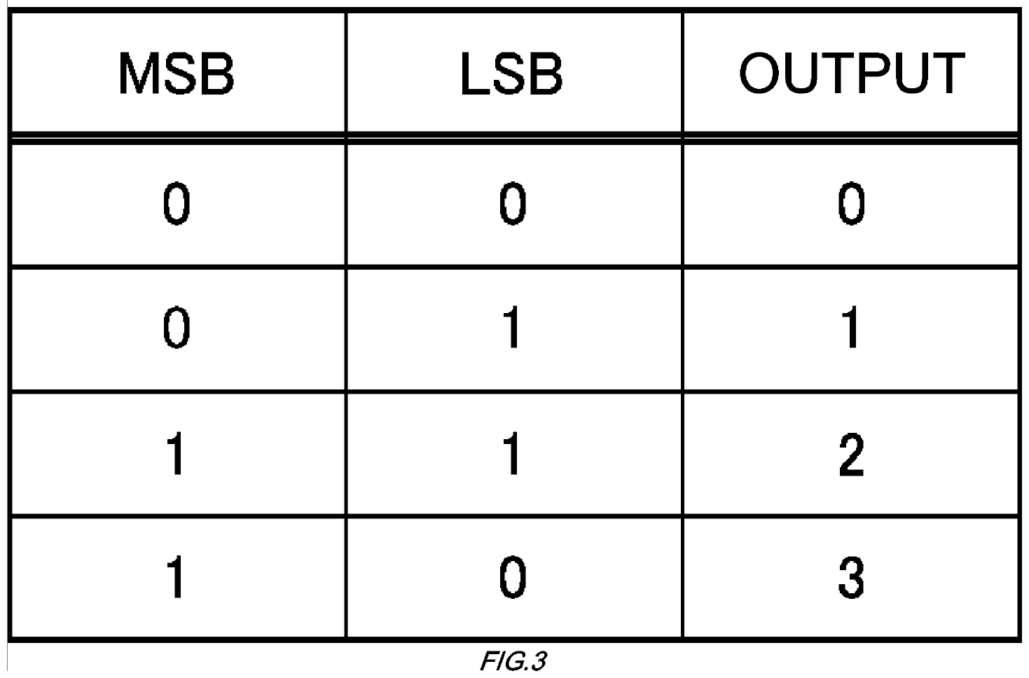

FIG. 3 is a table that shows Gray code conversions performed by a mapping section 130. The mapping section 130 converts transmission data including a most significant bit (MSB) outputted by the PRBS generator 110 and a least significant bit (LSB) outputted by the PRBS generator 120 into a multi-value symbol code which can have four values of 0 to 3 by converting it into a Gray code as shown in the table of the present figure.

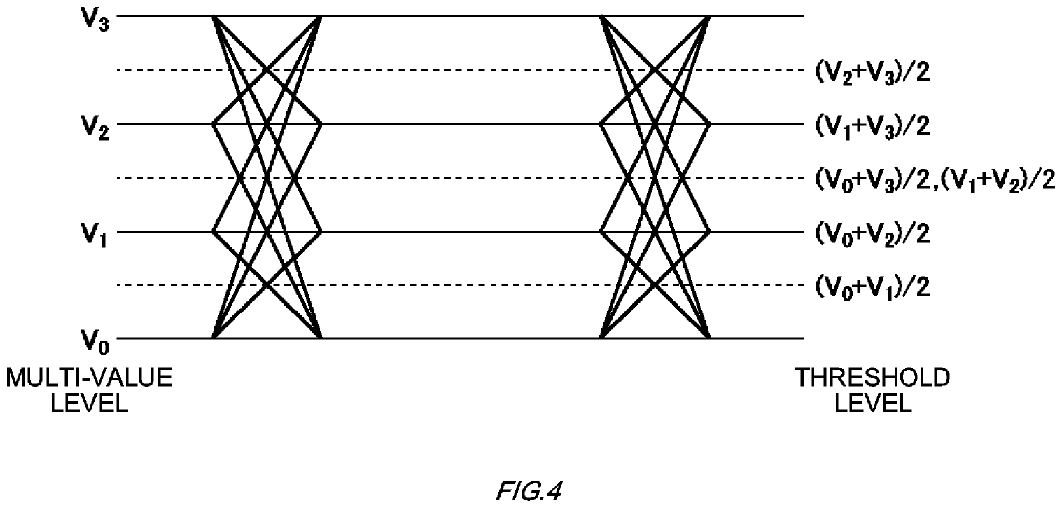

FIG. 4 shows a relation between a symbol transition of a PAM-4 signal and a threshold level. The encoder 140 encodes a Gray code 0 from the mapping section 130 into a symbol of voltage level V₀. Similarly, the encoder 140 encodes Gray codes 1 to 3 from the mapping section 130 into symbols of voltage level V₀ to V₃, respectively.

Two sequential symbols can each have any voltage level out of voltage levels V₀ to V₃. Accordingly, in jitter measurements of a certain symbol transition, a middle point between a voltage level of a symbol before the transition and a voltage level of the symbol after the transition is set as a threshold level, and a time point when a signal value of a symbol goes across the threshold level is measured. For example, in measuring a symbol transition from a symbol of voltage level V₀ to a symbol level of voltage level V₃, the threshold level is set to be (V₀+V₃)/2.

In this way, when a symbol transition between symbols of multi-value signals is measured, it is required to suitably switch the threshold according to a symbol transition. In contrast to this, when a symbol transition between symbols of binary signals is measured, the threshold may be kept constant at the middle voltage between a high level voltage and a low level voltage.

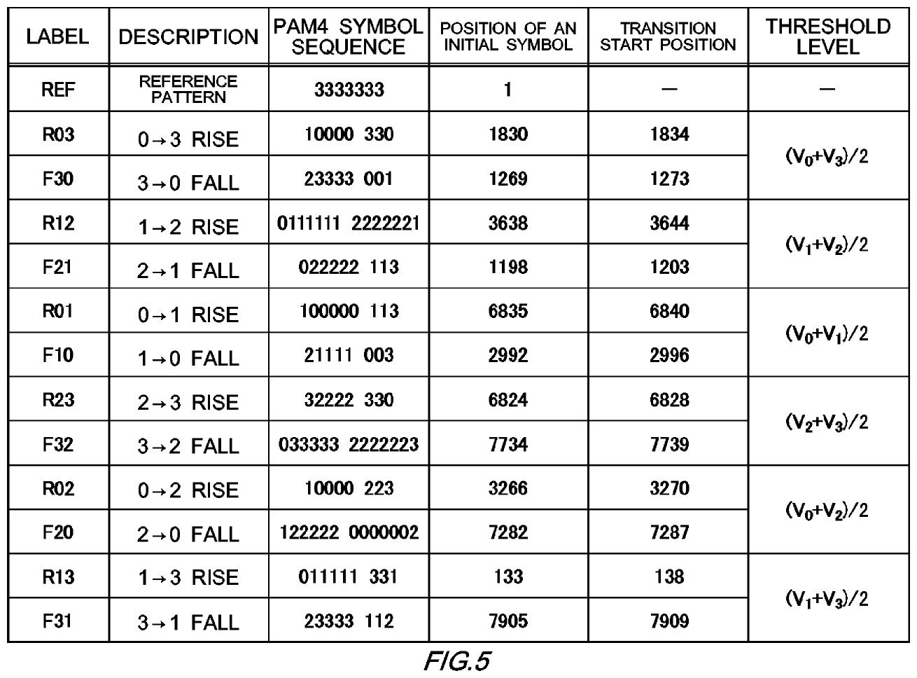

FIG. 5 shows one example of patterns of symbols that are subject to jitter measurements. In the example of this figure, patterns of symbols that are subject to jitter measurements defined by the standard of 200GAUI and 400GAUI are shown together with a reference pattern. The table shown in this figure shows “DESCRIPTION,” “PAM-4 SYMBOL SEQUENCE,” “POSITION OF AN INITIAL SYMBOL,” “TRANSITION START POSITION,” and “THRESHOLD LEVEL” for each of patterns shown by each label shown in the column of “LABEL.”

The pattern shown as “REF,” as shown in the “DESCRIPTION,” is a reference pattern that the DUT 100 transmits in the beginning of a pattern under test. That is to say, the DUT 100 transmit a pattern having a length of 7 shown as “3333333” in the “PAM-4 SYMBOL SEQUENCE” from the beginning of each pattern under test (the “POSITION OF AN INITIAL SYMBOL” is 1).

The pattern shown as “R03,” as shown in the “DESCRIPTION,” is a pattern that is subject to jitter measurements of rising from a symbol 0 to a symbol 3. “R03” is a pattern shown as “10000330” in the “PAM-4 SYMBOL SEQUENCE,” and starts from the symbol position of 1,830th (corresponding to S[1829]) in the PRBS13Q. The symbol transition that is subject to jitter measurements is a symbol transition from the last “0” of “10000” to the initial “3” of “330,” and its transition start position is the 1,834th symbol position. Because “R03” is a symbol transition from a symbol 0 to a symbol 3, the threshold used in jitter measurements is (V₀+V₃)/2 (see FIG. 4). Similarly, regarding all kinds of symbol transitions in which symbol values change between two sequential symbols, FIG. 5 designates, portion by portion, the symbol transition that is subject to jitter measurements during a pattern under test of a PRBS13Q.

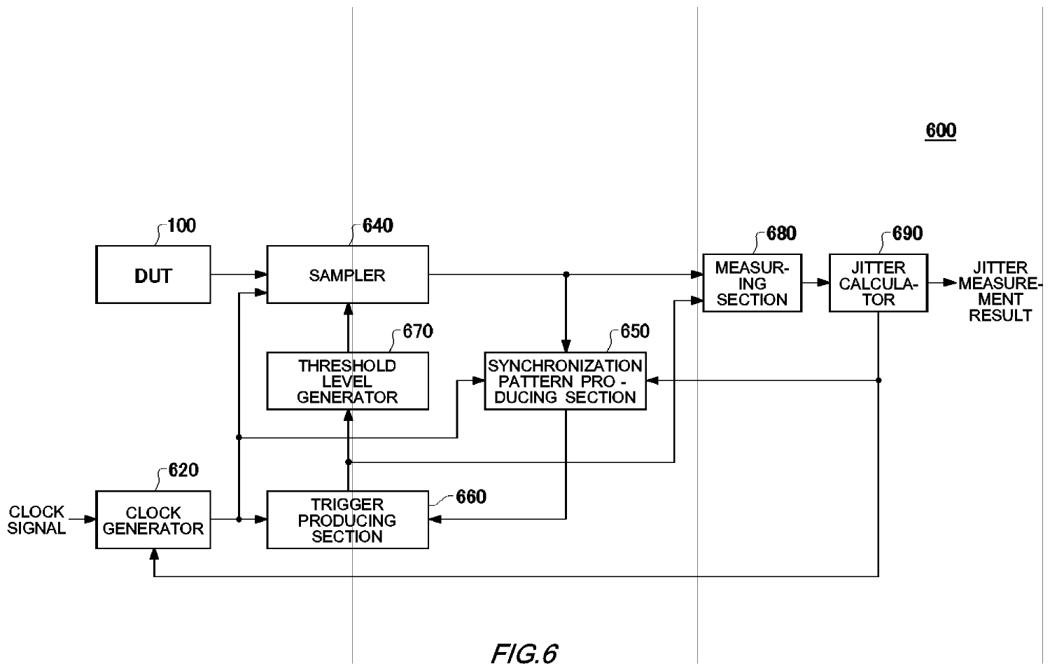

FIG. 6 shows a configuration of a measurement apparatus 600 according to the present embodiment. A measurement apparatus that measures jitters of the DUT 100 is required to specify a time point of a symbol transition according to the pattern shown in FIG. 5 out of patterns under test having symbol cycle that is synchronized with a high-speed clock signal, and to detect, if the symbol is a multi-value signal, the signal under test at the threshold level corresponding to the symbol transition. When such an operation is handled with a processing speed corresponding to a high-speed clock signal, it ends up in resulting in an increase in the scale of a circuit of a measurement apparatus. Therefore, a measurement apparatus 600 according to the present embodiment enables measuring jitters of a symbol transition included in patterns under test by using a sampling clock that is slower than a clock signal having a symbol cycle.

The measurement apparatus 600 connects to the DUT 100. The measurement apparatus 600 comprises a clock generator 620, a sampler 640, a synchronization pattern producing section 650, a trigger producing section 660, a threshold generator 670, a measuring section 680, and a jitter calculator 690. The clock generator 620 generates a sampling clock with a longer sampling cycle than a symbol cycle of a pattern under test including a symbol with a predefined number of symbols. The sampling cycle may have a cycle of an integer multiple of two or more times a symbol cycle. In the present embodiment, the clock generator 620 produces a sampling clock by dividing a clock signal that sets a symbol cycle of a pattern under test as one cycle.

In the present embodiment, the case that the clock generator 620 generates a sampling clock resulting from dividing a clock signal by 2×M is illustrated. The M is, as one example, 16. Furthermore, the clock generator 620 may input a clock signal supplied to the DUT 100 so as to use the signal for generating a sampling clock. Instead of this, the clock generator 620 may regenerate a clock signal by a clock recovery from a signal under test outputted by the DUT 100 so as to use the clock signal for generating a sampling clock.

The sampler 640 connects to the DUT 100, the clock generator 620, and the threshold generator 670. The sampler 640 samples a pattern under test that is repeatedly inputted from the DUT 100 according to a sampling clock from the clock generator 620. When each signal under test of patterns under test is a multi-value signal, the sampler 640 samples patterns under test by using a threshold generated by the threshold generator 670.

Here, if a sampling cycle has the cycle of the first integer multiple (two or more) times a symbol cycle, then the sampler 640 will sample symbols of the patterns under test at the intervals of the first integer multiple. Accordingly, the sampler 640 can keep sampling patterns under test at multiple portions while shifting to different sampled portions at the intervals of the first integer multiple. The clock generator 620 may define a sampling cycle in such a way that all the symbol transitions that are subject to jitter measurements as shown in FIG. 5 are included in portions possible to sample in this way.

Here, the clock generator 620 can define this first integer so as to make the first integer coprime with a number of symbols included in one cycle of patterns under test. In this case, the sampler 640 can sample each of all the symbols once each time while a pattern under test is repeated the first integer times. In the example of the present embodiment, the sampler 640 repeatedly inputs patterns under test having 8,191 symbols and samples symbols of signals under test at the interval of 32 (=2×M). In this case, if the sampler 640 samples S[0], S[32], . . . , S[8160] in the patterns under test of the first cycle, then the sampler 640 will sample, as the 8160+32nd symbol, 8160+32−8191=the first symbol S[1] in the second cycle. Similarly, the sampler 640 can continue to shift the position of symbols to sample by one position each time pattern under test is repeated, and can sample all the symbols while patterns under test are repeated 32 times.

The synchronization pattern producing section 650 connects to the clock generator 620 and the sampler 640. The synchronization pattern producing section 650 uses sampling clocks from the clock generator 620 so as to produce synchronization pattern synchronized to sampling patterns according to a predefined sequential number of sampling clocks in patterns under test. This synchronization pattern is to identify, with patterns, to which symbol position in the pattern under test the symbol sampled by the sampler 640 corresponds.

The trigger producing section 660 connects to the clock generator 620 and the synchronization pattern producing section 650. The trigger producing section 660 produces a trigger to an inputted pattern under test at a time point when a predefined symbol pattern as shown in FIG. 5 is generated. In the present embodiment, the trigger producing section 660 produces a trigger in response to that a sampling pattern to be sampled by the sampler 640 matches with a predefined comparison pattern. Here, the trigger producing section 660 uses a synchronization pattern outputted by the synchronization pattern producing section 650 as a sampling pattern to be sampled by the sampler 640, and produces a trigger in response to that the synchronization pattern matches with the comparison pattern.

The threshold generator 670 connects to the trigger producing section 660. The threshold generator 670 is provided for dynamically switching thresholds in the case that a pattern under test includes a symbol of a multi-value signal having three or more levels. The threshold generator 670 generates a threshold of level according to a symbol transition that is subject to jitter measurements, in response to a trigger generated by the trigger producing section 660.

The measuring section 680 connects to the sampler 640 and the trigger producing section 660. The measuring section 680 measures a sampling result of the sampler 640 in response to a sampling clock at a time point corresponding to a symbol transition that is subject to jitter measurements in patterns under test that are repeatedly inputted. The measuring section 680 can select and measure only a sampling result corresponding to a symbol transition that is subject to jitter measurements, by measuring a sampling result of the sampler 640 in response to a trigger generated by the trigger producing section 660.

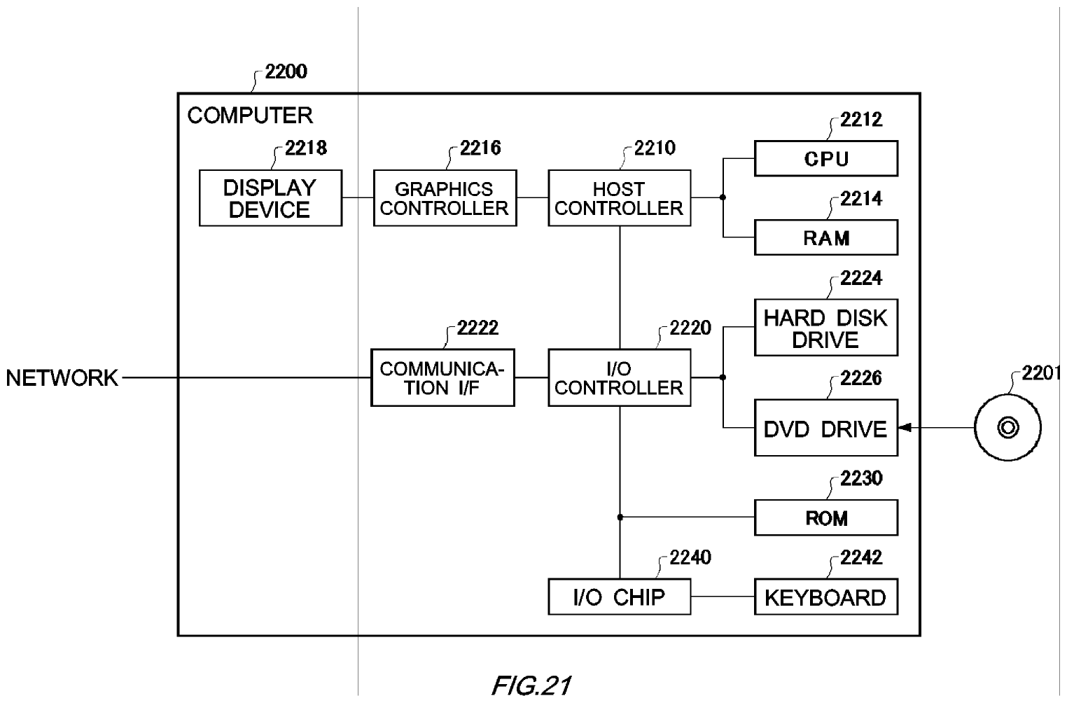

The jitter calculator 690 connects to the measuring section 680. The jitter calculator 690 may be a dedicated hardware realized by a dedicated circuitry designed for jitter calculations and may be a dedicated computer. Instead of this, the jitter calculator 690 may be, for example, a computer such as a PC (personal computer), a tablet computer, a smartphone, a workstation, a server computer, or a general-purpose computer, as illustrated in FIG. 21. The jitter calculator 690 calculates jitters of a pattern under test based on a measurement result by the measuring section 680. Also, the jitter calculator 690 may control each component within the measurement apparatus 600, such as the clock generator 620 and the synchronization pattern producing section 650, in order to eventually calculate jitters of a pattern under test.

The measurement apparatus 600 shown above allows the measurement of jitters of a symbol transition that is subject to measurements and is included in patterns under test, by using a sampling clock which is slower than a high-speed clock signal having a symbol cycle. Also, if the signal under test is a multi-value signal, the measurement apparatus 600 can comprise the threshold generator 670 and can generate a threshold of a level according to a symbol transition that is subject to measurement by the threshold generator 670.

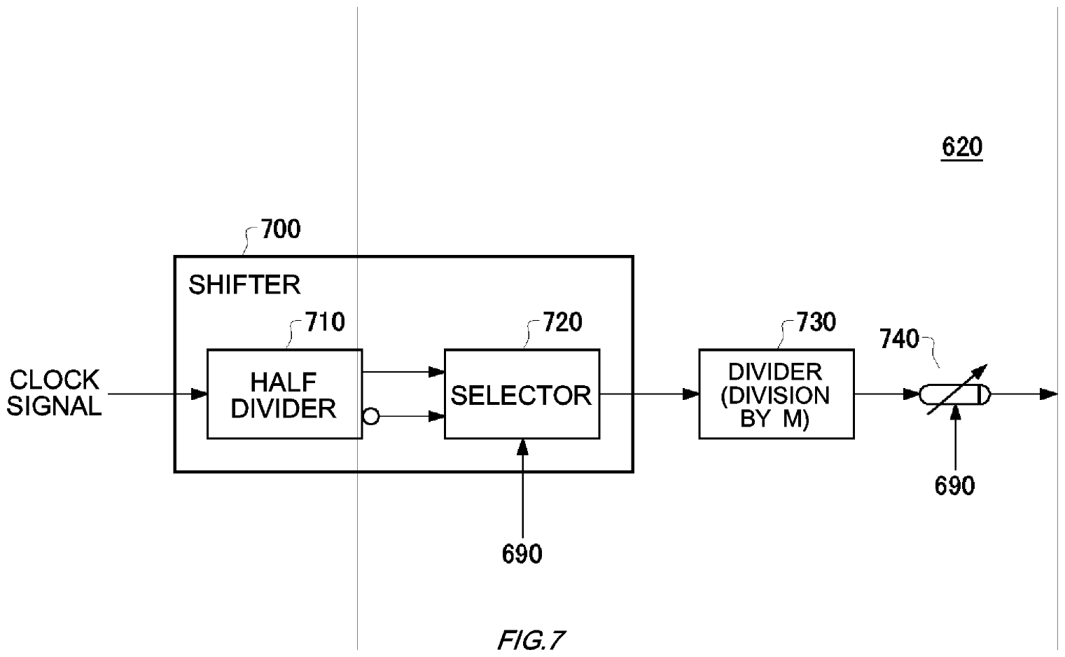

FIG. 7 shows a configuration of a clock generator 620 according to the present embodiment. The clock generator 620 has a shifter 700, a divider 730, and a variable delay circuit 740. The shifter 700 inputs clock signals. A clock signal is a clock whose symbol cycle is one cycle, and each symbol cycle is composed of a duration of H (high) level and a duration of L (low) level. The shifter 700 includes a circuit that enables switching whether or not to shift, by one cycle of symbol cycles, sampling clocks eventually outputted by the clock generator 620.

In the present embodiment, the shifter 700 includes a half divider 710 and a selector 720. The half divider 710 outputs a half division clock signal in which an H level and an L level are switched every symbol cycle, by half dividing a clock signal. Also, the half divider 710 outputs an inverted half division clock signal in which half division clock signals are inverted. In an inverted half division clock signal, a half division clock signal becomes an L level in a symbol cycle of an H level and becomes an H level in a symbol cycle of an L level.

The selector 720 connects to the half divider 710. The selector 720 selects which out of a half division clock signal and an inverted half division clock signal to output, in response to a shift instruction signal inputted by the jitter calculator 690. When outputting an inverted half division clock signal, the selector 720 will output a clock signal in which a time point to make a transition from an L level to an H level is shifted by one cycle of symbol cycles in comparison to the time when outputting a half division clock signal.

The divider 730 connects to the shifter 700. The divider 730 outputs a clock signal divided by 2M by additionally dividing a clock signal outputted by the shifter 700 by M. A variable delay circuit 740 connects to the divider 730. The variable delay circuit 740 outputs as a sampling clock by delaying a clock signal inputted from the divider 730 by an amount of delay according to a setting of an amount of delay from the jitter calculator 690. Thereby, for jitter measurements, the variable delay circuit 740 enables sampling signals under test in each phase by sweeping sampling clocks, for example, within a range of approximately a symbol cycle.

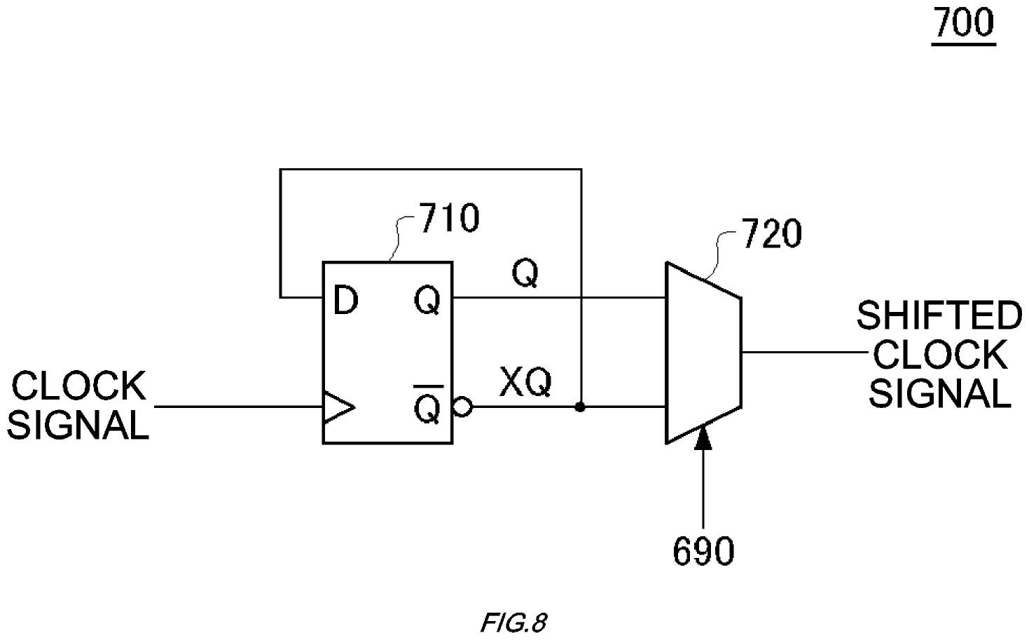

FIG. 8 shows an example of a circuit configuration of a shifter 700 according to the present embodiment. The half divider 710 may be realized by a D-FF (D flip-flop) having a D input, a clock input, a Q output, and an inverted Q output. In the half divider 710, by inputting an inverted Q output into a D input, its Q output is inverted each time a clock signal rises (a transition from an L level to an H level). Thereby, a Q output of the half divider 710 switches in the order of an H level, an L level each time a clock signal rises every symbol cycle. An inverted Q output of the half divider 710 will be an inverted value of a Q output.

The selector 720 selects a Q output or an inverted Q output in response to a shift instruction signal from the jitter calculator 690. Thereby, the selector 720 outputs a shifted clock signal whose phase is correspondingly shifted by a symbol cycle in response to a shift instruction signal.

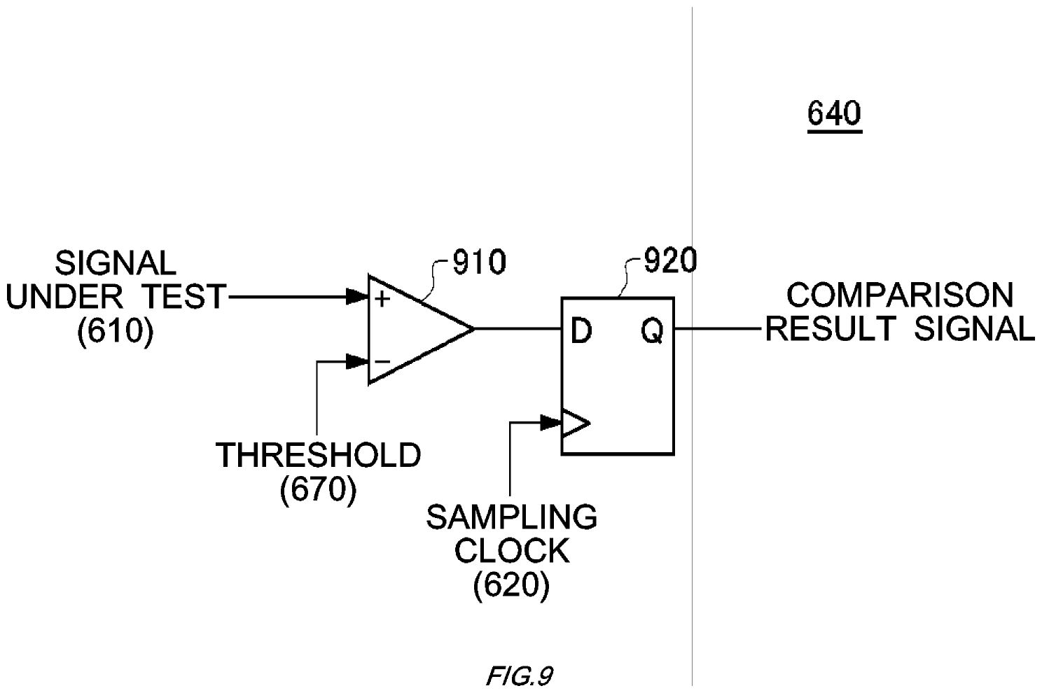

FIG. 9 shows a configuration of a sampler 640 according to the present embodiment. The sampler 640 has a comparator 910 and a D-FF 920.

The comparator 910 compares a signal under test from the DUT 100 with a threshold from the threshold generator 670. The comparator 910 according to the present embodiment outputs a comparison result which becomes an H level in response to that a level of a signal under test is higher than a threshold level and becomes an L level in response to that a level of a signal under test is lower than a threshold.

The D-FF 920 connects to the comparator 910. The D-FF 920 latches a comparison result of the comparator 910 in response to a rise of a sampling clock so as to output as a comparison result signal.

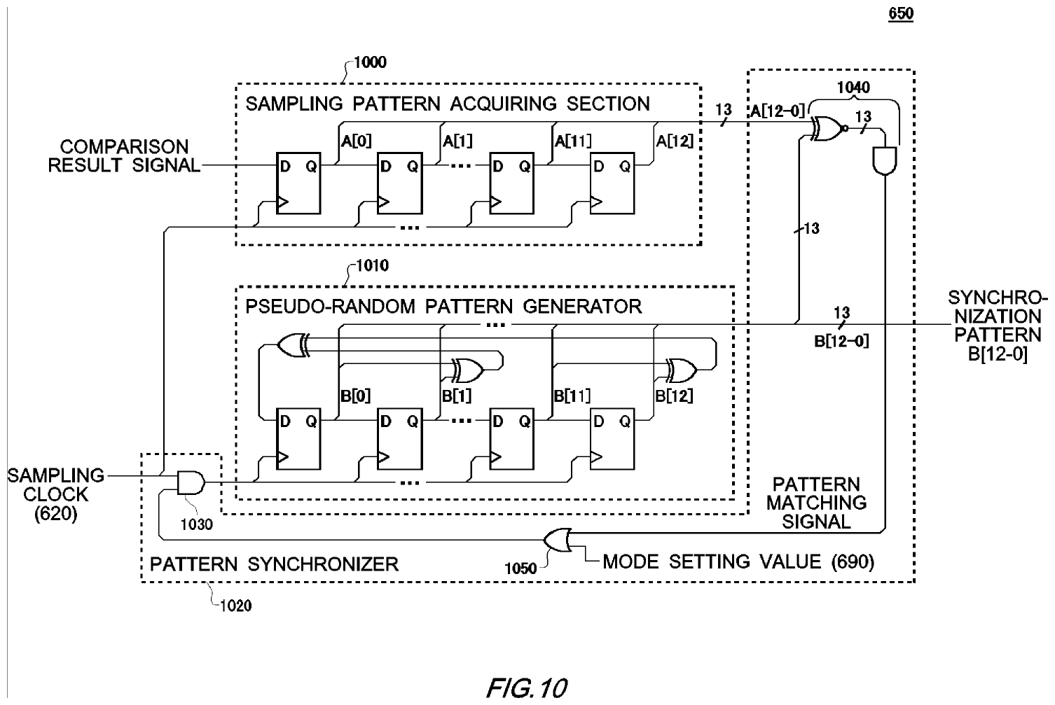

FIG. 10 shows a configuration of a synchronization pattern producing section 650 according to the present embodiment. The synchronization pattern producing section 650 has a sampling pattern acquiring section 1000, a pseudo-random pattern generator 1010, and a pattern synchronizer 1020.

The sampling pattern acquiring section 1000 includes a shift register composed of a plurality of cascaded D-FFs. The sampling pattern acquiring section 1000 acquires sampling patterns A[0] to A[12] (also shown as “A[12-0]”) according to a predefined sequential number sampling clocks in patterns under test, by continuing to sequentially shift a comparison result signal captured in a shift register according to sampling clocks. In the present embodiment, the sampling pattern acquiring section 1000 stores 13 symbols worth of comparison result signals, corresponding to that the pseudo-random pattern generator 1010 generates PRBS by using 13 bits worth of D-FFs in a similar manner to the PRBS generator 110.

The pseudo-random pattern generator 1010 includes a shift register composed of a plurality of cascaded D-FFs, and a circuit including a plurality of exclusive-or (XOR) elements and configured to feedback two or more D-FF outputs to the first grade D-FF of a shift register. The pseudo-random pattern generator 1010 generates the same pseudo-random pattern as a pattern that extracted, with a sampling clock, a pseudo-random pattern used to generate a pattern under test. The pseudo-random pattern generator 1010 according to the present embodiment generates the same pseudo-random pattern B[12-0] as a pattern gained by extracting, at the interval of 2M symbols, pseudo-random patterns generated by the PRBS generator 110.

The pattern synchronizer 1020 connects to the sampling pattern acquiring section 1000 and the pseudo-random pattern generator 1010. The pattern synchronizer 1020 performs a process to synchronize a sampling pattern outputted by the sampling pattern acquiring section 1000 and a pseudo-random pattern generated the pseudo-random pattern generator 1010, in a training mode that synchronizes a pseudo-random pattern generated by the pseudo-random pattern generator 1010 with a pseudo-random pattern extracted from patterns under test. Specifically, the pattern synchronizer 1020 synchronizes a pseudo-random pattern generated by the pseudo-random pattern generator 1010 with a pattern extracted, from the patterns under test, according to a predefined sequential number of sampling clocks (13 in the present embodiment).

The pattern synchronizer 1020 has an AND gate 1030, a matching detection circuit 1040, and an OR gate 1050. The AND gate 1030 functions as a clock gate by outputting a logical conjunction of outputs by a sampling clock and the OR gate 1050, as a clock of the pseudo-random pattern generator 1010. Specifically, when an output of the OR gate 1050 is a logic H, the AND gate 1030 supply a sampling clock to the pseudo-random pattern generator 1010. Also, when an output of the OR gate 1050 is a logic L, the AND gate 1030 sets the output of the AND gate 1030 as a logic L, and stops the supply of sampling clocks to the pseudo-random pattern generator 1010.

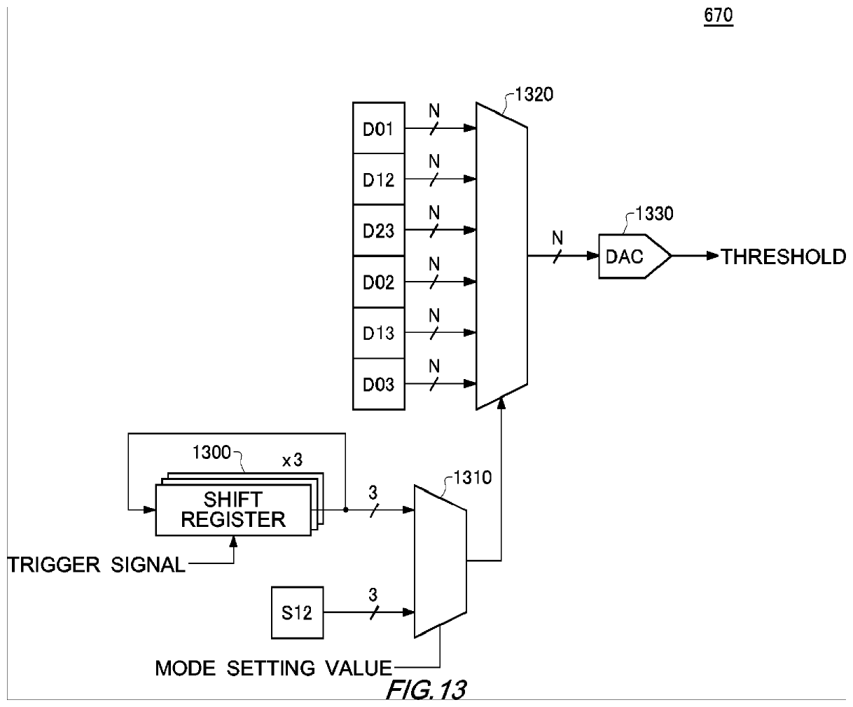

The matching detection circuit 1040 outputs a pattern matching signal that becomes a logic H when a sampling pattern A[12-0] outputted by the sampling pattern acquiring section 1000 matches with a pseudo-random pattern B[12-0] outputted by the pseudo-random pattern generator 1010, and becomes a logic L when they do not match. The OR gate 1050, in a training mode in which a mode setting value becomes a logic L, outputs a logic L and stops the supply of sampling clocks to the pseudo-random pattern generator 1010 while the pattern matching signal is a logic L. Here, as described below with reference to FIG. 13, in a training mode, the threshold generator 670 sets a threshold so that the sampler 640 can extract, from a pattern under test, a pseudo-random pattern outputted by the PRBS generator 110.

Thereby, in a training mode, while pseudo-random patterns B[12-0] of the pseudo-random pattern generator 1010 are kept constant at the same value, sampling patterns A[12-0] of the sampling pattern acquiring section 1000 change according to sampling clocks. A sampling pattern A[12-0] of the sampling pattern acquiring section 1000 will be a value that results from extracting a pseudo-random pattern outputted by the PRBS generator 110 according to a sampling clock. Here, a sampling pattern that results from extracting a pseudo-random pattern generated by the PRBS generator 110 at the interval of 2M symbols and sampling the same number times as the bits that the PRBS generator 110 has, is generated in the same order as a pseudo-random pattern generated by the pseudo-random pattern generator 1010.

When a sampling pattern A[12-0] of the sampling pattern acquiring section 1000 changes, it eventually matches with a pseudo-random pattern B[12-0]. Because a pattern matching signal becomes a logic H according to this, an output of the OR gate 1050 also becomes a logic H, and thus a sampling clock will be supplied to the pseudo-random pattern generator 1010. Here, a sampling pattern A[12-0] results from extracting a pseudo-random pattern generated by the PRBS generator 110 at the interval of 2M symbols, and changes in the same order as a pseudo-random pattern generated by the pseudo-random pattern generator 1010. Accordingly, subsequently after this, at the time points of sampling clocks, the pseudo-random pattern generator 1010 can outputs, as a synchronization pattern B[12-0], a pseudo-random pattern that matches with a pattern that extracted a pseudo-random pattern of the PRBS generator 110 included in patterns under test at the interval of 2M symbol.

After temporarily establishing a synchronization in a training mode, the jitter calculator 690 sets a mode setting value to be a logic H and to be a measurement mode. In a measurement mode, the pseudo-random pattern generator 1010 always outputs a synchronization pattern synchronized with a pattern that extracts a pseudo-random pattern of the PRBS generator 110 at the interval of 2M symbols. Thus, the threshold generator 670 may change a threshold according to a symbol transition that is subject to jitter measurements, and thereby a sampling pattern acquired by the sampling pattern acquiring section 1000 may differ from a pattern that extracts a pseudo-random pattern of the PRBS generator 110 at the interval of 2M symbols.

According to the synchronization pattern producing section 650 according to the present embodiment, in a training mode, a sampling pattern of a pseudo-random pattern of the PRBS generator 110 extracted from patterns under test is synchronized with a pseudo-random pattern of the pseudo-random pattern generator 1010. Thereby, even if the threshold generator 670 changes a threshold in a measurement mode, the synchronization pattern producing section 650 can output a synchronization pattern synchronized with an extracted pseudo-random pattern of the PRBS generator 110 included in patterns under test.

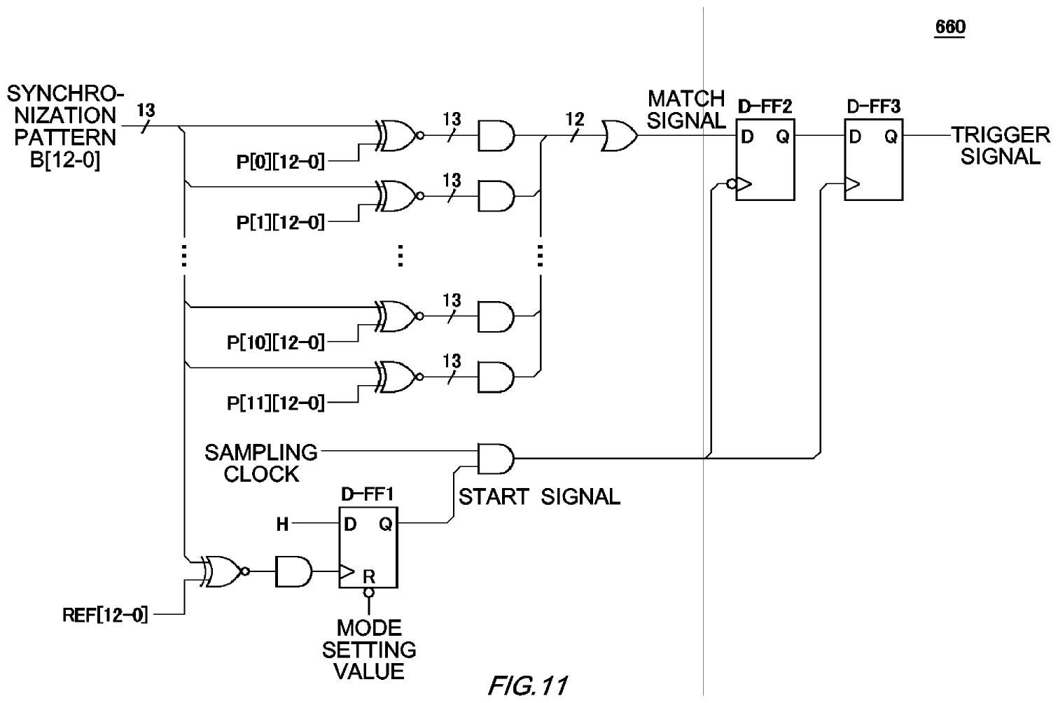

FIG. 11 shows a configuration of a trigger producing section 660 according to the present embodiment. The trigger producing section 660 has a D-FF1, a D-FF2, a D-FF3, and a plurality of logic elements. The D-FF1 inputs a fixed logic H into a D input, inputs, into a clock input, a signal that rises when a synchronization pattern from the synchronization pattern producing section 650 matches with a reference pattern, and inputs, into a reset input, an inverted value of a mode setting value from the jitter calculator 690. During a training mode in which a mode setting value becomes a logic L, the D-FF1 will be in a reset state and set, to be a logic L, a Q output that becomes a start signal. Thereby, an AND gate that inputs a sampling clock and a start signal stops supplying sampling clocks to the D-FF2 and the D-FF3 during a training mode.

After switching from a training mode to a measurement mode, the D-FF1 sets a start signal to be a logic H in response to that a synchronization pattern B[12-0] matches with a reference pattern corresponding to “REF” in FIG. 5. Thereby, the D-FF1 starts the supply of sampling clocks to the D-FF2 and the D-FF3. Furthermore, a synchronization pattern B[12-0] is synchronized with a pattern that extracts a pseudo-random pattern outputted by the PRBS generator 110. Therefore, the trigger producing section 660 uses a pattern corresponding to a pattern that extracts a pseudo-random pattern of the PRBS generator 110 until the time point when a reference pattern in FIG. 5 starts, as a reference pattern REF[12=0] for comparing with a synchronization pattern B[12-0].

The D-FF2 inputs, into a D input, a matching signal that becomes a logic H when a synchronization pattern B[12-0] matches with any of a plurality of patterns P[0] to P[12], and becomes a logic L when the synchronization pattern does not match with any of a plurality of comparison patterns P[0] to P[12]. The D-FF2 latches a matching signal so as to output it from a Q output, at a time point when a sampling clock is inverted subsequently after a reference pattern is detected in a measurement mode. Here, a plurality of patterns P[0] to P[12] each corresponds to a sampling pattern at a time point of a symbol transition to be measured in “R03,” “R30,” . . . in FIG. 5. The trigger producing section 660, in a similar manner to a reference pattern, uses a pattern corresponding to a set of MSB of each symbol of a sampling pattern at a time point of a symbol transition to be measured, for example, in “R03” as each of a plurality of patterns P[0] to P[12].

The D-FF3 latches a comparison pattern matching signal outputted by the D-FF1 so as to output it from a Q output as a trigger signal, at a time point of a sampling clock subsequently after a reference pattern is detected in a measurement mode.

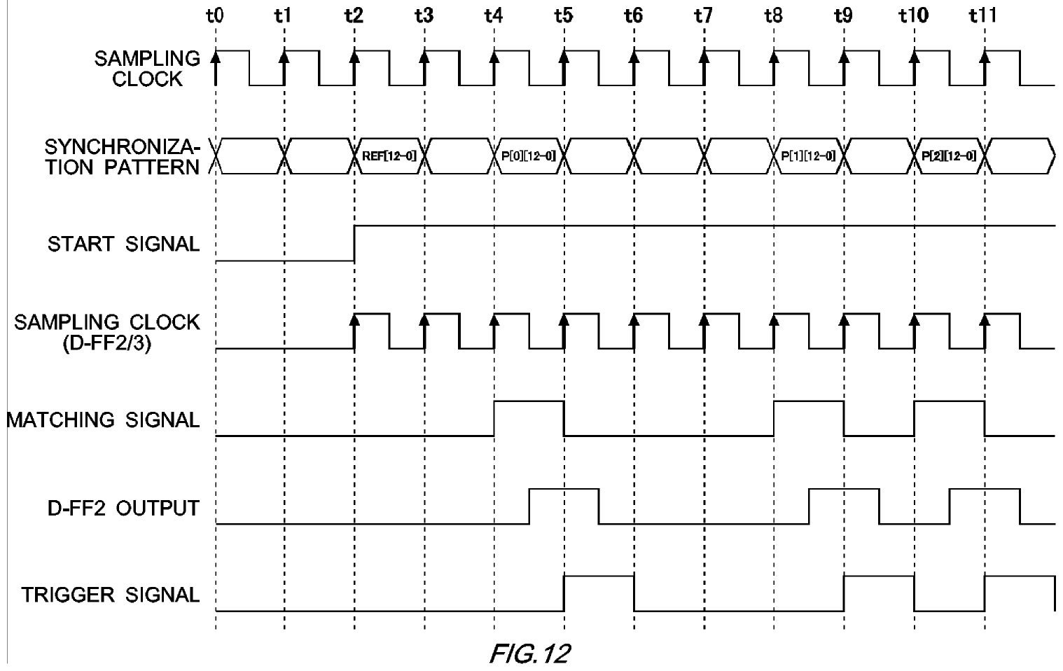

FIG. 12 is a time point chart that shows one example of an operation of a synchronization pattern producing section 650 and a trigger producing section 660 according to the present embodiment. This figure shows a waveform that goes with a lapse of time in the lateral direction for each of a sampling clock, a synchronization pattern, a start signal, a sampling clock supplied to a D-FF2 and a D-FF3, a matching signal, an output of a D-FF2, and a trigger signal.

When a synchronization pattern matches with a reference pattern REF[0-12] at a time t2, the D-FF1 sets a start signal as a logic H, and start the supply of a sampling clock to the D-FF2 and the D-FF3. When a synchronization pattern matches with a pattern P[0] at a time t4, a matching signal becomes a logic H. The D-FF2 latches a matching signal of logic H at a time point when a sampling clock is inverted, and the D-FF3 latches an output of the D-FF2 at a time point of a sampling clock so as to set a trigger signal to be a logic H at a time t5, which is the next cycle of a sampling clock.

The trigger producing section 660 shown above, by using a synchronization pattern, can produce a trigger in response to that a sampling pattern according to a predefined sequential number in patterns under test of sampling clocks matches with any of a plurality of comparison patterns that are patterns of signals under test corresponding to time points of each symbol transition to be measured.

FIG. 13 shows a configuration of a threshold generator 670 according to the present embodiment. The threshold generator 670 has a shift register 1300, a selector 1310, a selector 1320, and a DAC 1330. The shift register 1300, for each symbol transition as shown in FIG. 5, stores a selected value of a threshold in the order of appearance of symbol transitions. In the present embodiment, because there are 6 kinds of thresholds, the shift register 1300 stores a selected value of 3 bits for each symbol transition. For the selected value of a threshold, for example, a value 0 indicates a threshold between symbol values 0 to 1, (V₀+V₁)/2, the value 1 indicates a threshold between symbol values 1 to 2, (V₁+V₂)/2, the value 2 indicates a threshold between symbol values 2 to 3, (V₂+V₃)/2, the value 3 indicates a threshold between symbol values 0 to 2, (V₀+V₂)/2, the value 4 indicates a threshold between symbol values 1 to 3, (V₁+V₃)/2, and the value 5 indicates a threshold between symbol values 0 to 3, (V₀+V₃)/2.

Because there are twelve symbol transitions to be measured as shown in FIG. 5, the shift register 1300 stores selected values of a threshold for 12 selected values worth in the order of appearance in sampling by sampling clock. The shift register 1300 continues to shift outputted selected values of thresholds each time a trigger signal of logic H is inputted, and returns to the initial selected value when outputting the last selected value.

The selector 1310 selects, in a training mode, a selected value S12 (=value 1) that selects a threshold for sampling a pseudo-random pattern outputted by the PRBS generator 110, (V₁+V₂)/2. Here, a pseudo-random pattern outputted by the PRBS generator 110 is encoded into a MSB of each symbol after being converted into a Gray code. Therefore, the threshold generator 670, during a training mode, by setting a threshold to be (V₁+V₂)/2, makes a pseudo-random pattern outputted by the PRBS generator 110 able to sample. Also, the selector 1310, in a measurement mode, selects a selected value outputted by the shift register 1300.

The selector 1320 selects a digital threshold that corresponds to a selected value, out of a plurality of digital thresholds D01, D12, D23, D02, D13, and D03 according to a selected value from the selector 1310. The DAC 1330 performs a D/A conversion of a selected digital threshold into an analog threshold so as to output it.

The threshold generator 670 shown above, in a training mode, can enable generating a threshold for extracting, from a pattern under test, a pseudo-random pattern used to generate a pattern under test. Also, the threshold generator 670, in a measurement mode, can generate a threshold corresponding to each symbol transition to be measured by switching thresholds each time a trigger signal is inputted.

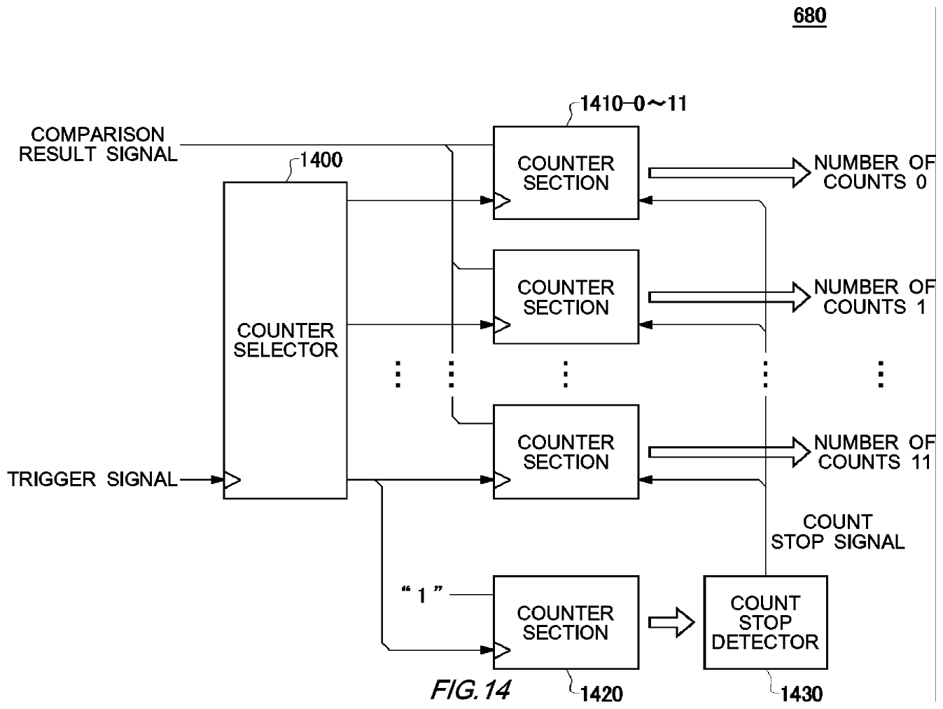

FIG. 14 shows a configuration of a measuring section 680 according to the present embodiment. The measuring section 680 has a counter selector 1400, a plurality of counter sections 1410-0 to 1410-11, a counter section 1420, and a count stop detector 1430. Each time receiving a trigger signal, the counter selector 1400 outputs a clock for counting to the counter section 1410 that measures a corresponding symbol transition out of a plurality of counter sections 1410-0 to 1410-11. The counter selector 1400 may cause the counter section 1410-0 to count in response to a first trigger, may cause the counter section 1410-1 to count in response to a second trigger, and, in a similar manner for the following, may cause the counter sections 1410 to count, one by one in the order.

Each of the counter sections 1410-0 to 1410-11 is provided correspondingly to each of symbol transitions that is subject to jitter measurements. In the present embodiment, because there are twelve symbol transitions to be measured as shown in FIG. 5, twelve counter sections 1410 are prepared. The counter sections 1410-0 to 1410-11 are reset before a measurement mode starts. After a measurement mode starts, the counter section 1410-0 counts a comparison result signal for a symbol transition corresponding to a first trigger. Specifically, the counter section 1410-0 does not count up a value if the comparison result signal is 0, and counts up the value if the comparison result signal is 1. The counter section 1410-1 counts a comparison result signal for a symbol transition corresponding to a second trigger. In a similar manner for the following, the counter section 1410-11 counts a comparison result signal for a symbol transition corresponding to a twelfth trigger. Once patterns under test are repeated for one round of the counter sections 1410, the counter section 1410-0 counts a comparison result signal for a symbol transition corresponding to a thirteenth trigger which corresponds to the same symbol position as a symbol transition corresponding a first trigger in patterns under test. In a similar manner for the following, the counter sections 1410-0 to 1410-11 counts a comparison result signal in the order for every trigger, and goes back to the counter section 1410-0 after the counter section 1410-11 so as to continue counting.

The counter section 1420 is reset before a measurement mode starts. The counter section 1420 inputs the same clocks for counting as the counter section 1410-11 so as to count a number of clocks for counting. The count stop detector 1430 sets a count stop signal as a logic H in response to that the count value of the counter section 1420 becomes a preset number of counts, and stops the counting by the counter sections 1410-0 to 1410-11.

The measuring section 680 shown above allows each counter section 1410 to sample, for example, 100,000 times each, a comparison result of a symbol transition of a symbol position corresponding to its counter section 1410 in patterns under test that are repeatedly inputted. For example, if the count value was 35,000 in a symbol transition from a symbol 0 to symbol 3, 65,000 times (65%) would be considered to be counted as a state before a transition and 35,000 times (35%) would be considered to be counted as a state before a transition, at a time point of a sampling clock. Here, in a similar manner to the symbol transition from a symbol 3 to a symbol 0, in a symbol transition in which a symbol value decreases, a state before a transition is counted as 1, and a state after a transition is counted as 0. Accordingly, by reducing a count value from the number of counts 100,000, a ratio of being after a symbol transition at a time point of sampling can be calculated.

The jitter calculator 690 can gain jitter histograms for all kinds (12 kinds in the present embodiment) of symbol transitions by causing the above-described counting to be repeated 100,000 times each while an amount of delay of the variable delay circuit 740 continues to be changed by a microscopic amount of delay each time. A jitter histogram indicates in what ratio is being after a transition in each phase.

The jitter calculator 690 may calculate a jitter histogram for all the symbol transitions by add together jitter histograms of all kinds of symbol transitions. The jitter calculator 690 may calculate, from a jitter histogram for all the symbol transitions, a peak-to-peak jitter value and a RMS jitter value of a time when a BER (bit error rate) becomes a value defined by a standard (for example, 10⁻⁴). The peak-to-peak jitter value corresponds to a J4U jitter value in 200GAUI and 400GAUI, and the RMS jitter value corresponds to a JRMS jitter value in 200GAUI and 400GAUI.

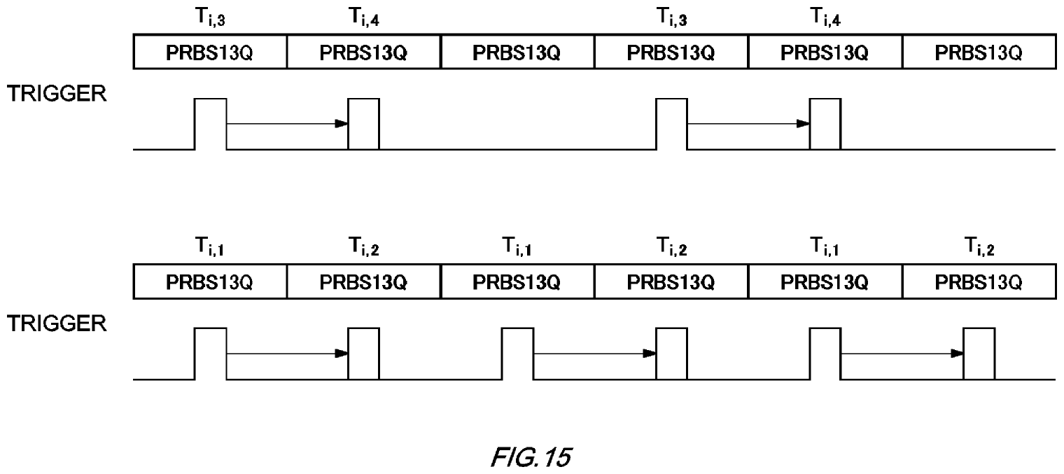

FIG. 15 shows one example of an measurement method of EOJ (even-odd jitter). For example, in 200GAUI and 400GAUI, it is determined to measure an EOJ under the assumption that the DUT 100 outputs each symbol by interleaving of a plurality of transmitters. A measurement of an EOJ includes (1) measuring an average value of a symbol transition time at the interval of three times the pattern length of a PRBS13Q that becomes a pattern under test (8,191 symbols), and (2) measuring an average value of a symbol transition time at the interval of twice the pattern length of a PRBS13Q that becomes a pattern under test (8,191 symbols).

The upper portion of FIG. 15 shows the measurement method of (1). The measurement apparatus 600 measures an average value T_{i, 3} of symbol transition time for a certain symbol transition i, in a first PRBS13Q, in a fourth PRBS13Q, which is three times the pattern length after the first, and in each PRBS13Q subsequently at the interval of three times the pattern length. In addition, the measurement apparatus 600 measures an average value T_{i, 4} of symbol transition time for the symbol transition i, in a second PRBS13Q, which will be one after the present, in a fifth PRBS13Q, which is three times the pattern length after the second, and in each PRBS13Q subsequently at the interval of three times the pattern length.

The lower portion of FIG. 15 shows the measurement method of (2). The measurement apparatus 600 measures an average value T_{i, 1} of symbol transition time for a certain symbol transition i, in a first PRBS13Q, in a third PRBS13Q, which is twice the pattern length after the first, in a fifth PRBS13Q, which is further twice the pattern length after the third, and in each PRBS13Q subsequently after that at the interval of twice the pattern length. In addition, the measurement apparatus 600 measures an average value T_{i, 2} of symbol transition time for the symbol transition i, in a second PRBS13Q, which will be one after the present, in a fourth PRBS13Q, which is twice the pattern length after the second, in a sixth PRBS13Q, which is further twice the pattern length after the fourth, and in each PRBS13Q subsequently after that at the interval of twice the pattern length.

The jitter calculator 690 calculate an EOJᵢ of a symbol transition i by the following equation (1):

EOJᵢ=|(T_{i,2}−T_{i,1})−(T_{i,4}−T_{i,3})| (1)

The jitter calculator 690 calculates an EOJᵢ that becomes the largest out of EOJᵢ of each symbol transitionᵢ as an EOJ of patterns under test fed by the DUT 100.

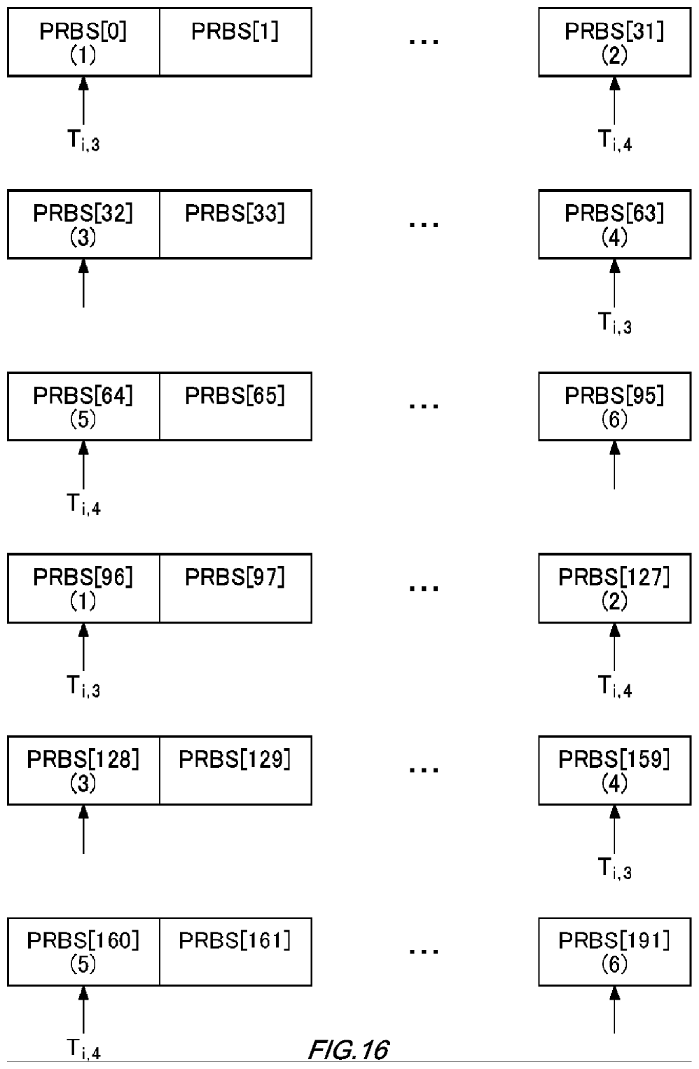

FIG. 16 shows the first example of a method to identify a symbol transition used for measuring EOJs, from repeated patterns under test. The measurement apparatus 600 performs a sampling of a symbol transition used in the measurement of T_{i, 3} and T_{i, 4} shown in the upper portion of FIG. 15, in the pattern shown in this figure.

In the present embodiment, the measurement apparatus 600 samples patterns under test of a PRBS13Q having 8,191 symbols at the interval of 2M (=32) symbols. Accordingly, the measurement apparatus 600 can sample a symbol transition i at a certain symbol position of patterns under test, each time patterns under test are repeated by 2M times. In this figure, patterns under test that are repeatedly inputted are indicated as PRBS[0], PRBS[1], . . . , and patterns under test of 2M times worth are laterally placed. In this figure, the measurement apparatus 600 samples symbol transition i in patterns under test PRBS[0], PRBS[32], PRBS[64], . . . , which are located in the leftmost and at the interval of 2M times.

As shown in the upper portion of FIG. 15 here, a symbol transition i that is subject to measurement of T_{i, 3} appears at a first pattern under test and a fourth pattern under test in repeated patterns under test of 6 times worth. In FIG. 16, when corresponding a pattern under test PRBS[0] to a first (0 mod 6+1=1) pattern under test in patterns under test repeated 6 times each, a symbol transition i sampled at PRBS[32] corresponds to a third (32 mod 6+1=3) pattern under test in patterns under test repeated 6 times each. As shown in the upper portion of FIG. 15, a third pattern under test is not used.

Then, a symbol transition i sampled at PRBS[64] corresponds to a fifth (64 mod 6+1=5) pattern under test in patterns under test repeated 6 times each. As shown in the upper portion of FIG. 15, a fifth pattern under test is used for measuring T_{i, 4}. Similarly, a symbol transition i sampled at PRBS[96] corresponds to a first (96 mod 6+1=1) pattern under test in patterns under test repeated 6 times each, and is used for measuring T_{i, 3}, and this is repeated in a similar manner for the following.

In this way, with reference to the upper portion of FIG. 15, the measurement apparatus 600 can repeatedly sample symbol transitions i corresponding to T_{i, 3} of a first pattern under test and T_{i, 4} of a fifth pattern under test. In contrast to this, if alone with patterns under test of the leftmost in FIG. 16, symbol transitions i corresponding to T_{i, 4} of a second pattern under test and T_{i, 3} of a fourth pattern under test in the upper portion of FIG. 15 cannot be sampled.

Therefore, the jitter calculator 690, by using a shift instruction signal, instructs to shift sampling clocks by one cycle of symbol cycles in order to sample symbol transitions i corresponding to T_{i, 4} of a second pattern under test and T_{i, 3} of a fourth pattern under test in the upper portion of FIG. 15. When sampling clocks are slid later by one cycle of symbol cycles, the measurement apparatus 600 can sample symbol transitions i in a pattern under test one pattern before a pattern under test that sampled symbol transitions i prior to shifting sampling clocks. For example, in FIG. 16, the measurement apparatus 600 can sample symbol transitions i in PRBS[31], PRBS[63], PRBS[95], . . . .

A symbol transition i sampled at PRBS[31] corresponds to a second (31 mod 6+1=2) pattern under test in patterns under test repeated 6 times each. As shown in the upper portion of FIG. 15, a second pattern under test is used for measuring T_{i, 4}. A symbol transition i sampled at PRBS[63] corresponds to a fourth (63 mod 6+1=4) pattern under test in patterns under test repeated 6 times each, and is used for measuring T_{i, 3}. A symbol transition i sampled at PRBS[95] corresponds to a sixth (95 mod 6+1=6) pattern under test in patterns under test repeated 6 times each, and is not used for measuring T_{i, 3} and T_{i, 4}.

In this way, the measurement apparatus 600 can sample symbol transitions i corresponding to T_{i, 4} of a second pattern under test and T_{i, 3} of a fourth pattern under test in the upper portion of FIG. 15, by shifting sampling clocks by one cycle of symbol cycles.

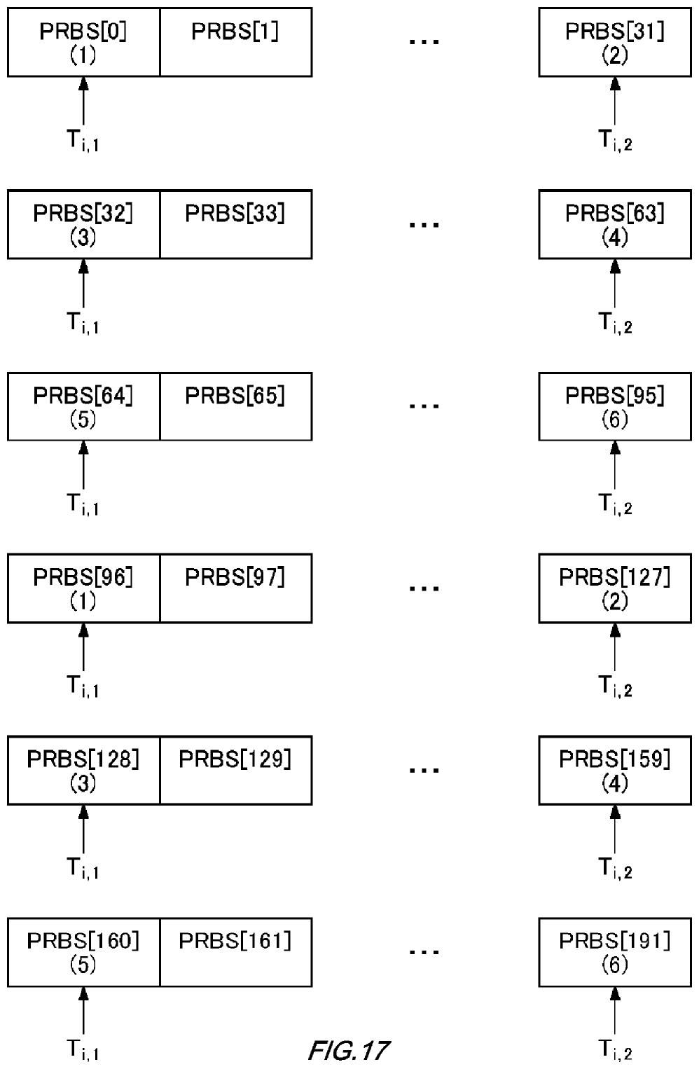

FIG. 17 shows the second example of a method to identify a symbol transition used for measuring EOJs, from repeated patterns under test. The measurement apparatus 600 performs a sampling of a symbol transition used in the measurement of T_{i, 1} and T_{i, 2} shown in the lower portion of FIG. 15, in the pattern shown in this figure.

Also in this figure, in a similar manner to in FIG. 16, patterns under test that are repeatedly inputted are indicated as PRBS[0], PRBS[1], . . . , and patterns under test of 2M times worth are laterally placed. The measurement apparatus 600 samples symbol transition i in patterns under test PRBS[0], PRBS[32], PRBS[64], . . . , which are located in the leftmost and at the interval of 2M times.

As shown in the lower portion of FIG. 15 here, a symbol transition i that is subject to measurement of T_{i, 1} appears at a first pattern under test, a third pattern under test, and a fifth pattern under test in repeated patterns under test of 6 times worth. In FIG. 17, when corresponding a pattern under test PRBS[0] to a first (0 mod 6+1=1) pattern under test in patterns under test repeated 6 times each, a symbol transition i sampled at PRBS[32] corresponds to a third (32 mod 6+1=3) pattern under test in patterns under test repeated 6 times each. Also, a symbol transition i sampled at PRBS[64] corresponds to a fifth (64 mod 6+1=5) pattern under test in patterns under test repeated 6 times each. These are used for measuring T_{i, 1} all as shown in the lower portion of FIG. 15. In a similar manner for the following, from the patterns under test in the leftmost of FIG. 17, only symbol transition i used for measuring T_{i, 1} can be sampled.

The jitter calculator 690, by using a shift instruction signal, instructs to shift sampling clocks by one cycle of symbol cycles in order to sample symbol transitions i corresponding to T_{i, 2} of a second, a fourth, a sixth patterns under test in the lower portion of FIG. 15. When sampling clocks are slid later by one cycle of symbol cycles, the measurement apparatus 600 can sample symbol transitions i in a pattern under test one pattern before a pattern under test that sampled symbol transitions i prior to shifting sampling clocks. For example, in FIG. 17, the measurement apparatus 600 can sample symbol transitions i in PRBS[31], PRBS[63], PRBS[95], . . . .

A symbol transition i sampled at PRBS[31] corresponds to a second (31 mod 6+1=2) pattern under test in patterns under test repeated 6 times each. As shown in the lower portion of FIG. 15, a second pattern under test is used for measuring T_{i, 2}. A symbol transition i sampled at PRBS[63] corresponds to a fourth (63 mod 6+1=4) pattern under test in patterns under test repeated 6 times each, and is used for measuring T_{i, 2}. A symbol transition i sampled at PRBS[95] corresponds to a fifth (95 mod 6+1=6) pattern under test in patterns under test repeated 6 times each, and is used for measuring T_{i, 2}.

In this way, the measurement apparatus 600 can sample symbol transitions i corresponding to T_{i, 2} of a second, fourth, and sixth patterns under test in the lower portion of FIG. 15, by shifting sampling clocks by one cycle of symbol cycles.

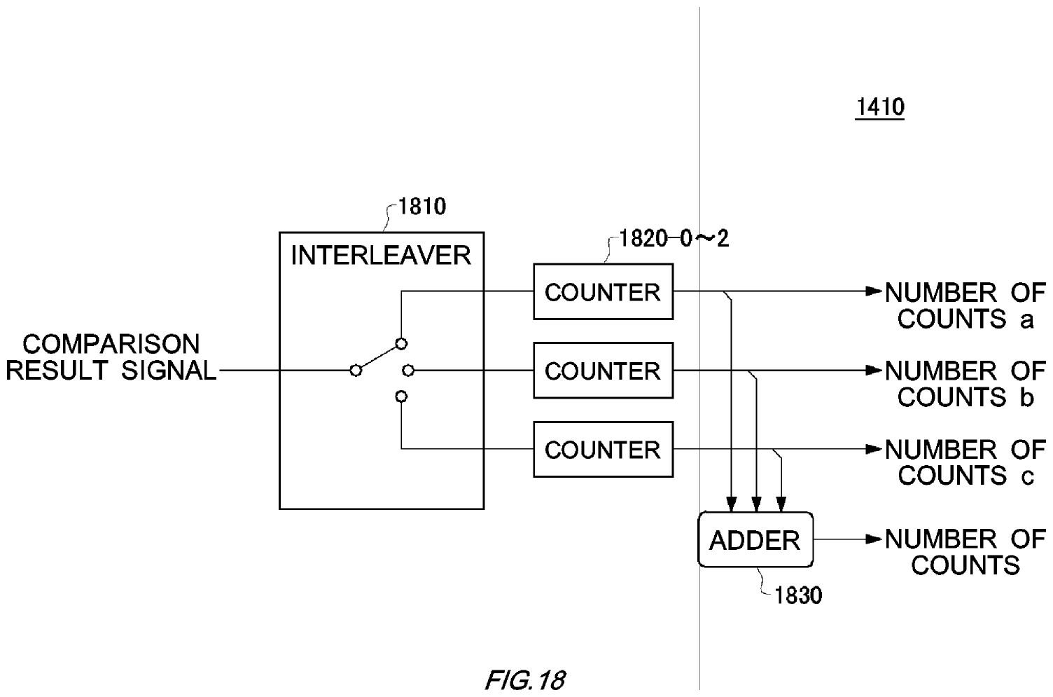

FIG. 18 shows a configuration of a counter section 1410 according to the present embodiment. In order to realize a measurement method of an EOJ shown in FIGS. 16 and 17, each counter section 1410 shown in FIG. 14 may have a configuration shown in this figure.

The counter sections 1410 shown in this figure includes an interleaver 1810, and a plurality of counters 1820-0 to 1820-2. The interleaver 1810 switches the counters 1820-0 to 1820-2 configured to count a comparison result signal, each time when sampling symbol transitions i from patterns under test. The interleaver 1810 may switch the counters 1820-0 to 1820-2, each time clock for counting is inputted from the counter selector 1400.

A plurality of counters 1820-0 to 1820-2 counts a comparison result signal in response to being selected by the interleaver 1810. In the present embodiment, the counter section 1410 includes three of the counters 1820. The counter 1820-0 counts a comparison result signal for a symbol transition i sampled from PRBS[0], PRBS[96], This allows the counter 1820-0 to count a comparison result signal for a symbol transition i used for measuring T_{i, 3}. Furthermore, when sampling clocks are shifted by one cycle of symbol cycles, the counter 1820-0 can count a comparison result signal for a symbol transition i used for measuring T_{i, 4}.

The counter 1820-1 counts a comparison result signal for a symbol transition i sampled from PRBS[32], PRBS[128], . . . . This allows the counter 1820-1 to count a comparison result signal for a symbol transition i used for measuring neither T_{i, 3} nor T_{i, 4}. Furthermore, when sampling clocks are shifted by one cycle of symbol cycles, the counter 1820-1 can count a comparison result signal for a symbol transition i used for measuring T_{i, 3}.

The counter 1820-2 counts a comparison result signal for a symbol transition i sampled from PRBS[64], PRBS[160], . . . . This allows the counter 1820-2 to count a comparison result signal for a symbol transition i used for measuring T_{i, 4}. Furthermore, when sampling clocks are shifted by one cycle of symbol cycles, the counter 1820-2 can count a comparison result signal for a symbol transition i used for measuring neither T_{i, 3} nor T_{i, 4}.

Furthermore, in the case of a measurement method in FIG. 17, the counters 1820-0 to 1820-2 count a comparison result signal for a symbol transition i all used for measuring T_{i, 1}. Also, when sampling clocks are shifted by one cycle of symbol cycles, the counters 1820-0 to 1820-2 can each count a comparison result signal for a symbol transition i all used for measuring T_{i, 2}.

The adder 1830 calculates and outputs a total of count values of a plurality of counters 1820-0 to 1820-2. This allows the adder 1830, in a measurement method of FIG. 17, to output a total count value for a symbol transition i used for measuring T_{i, 1} or T_{i, 2}.

By using the counter section 1410 shown in this figure, the measurement apparatus 600 counts a comparison result signal for symbol transition i that should be used for measuring T_{i, 3} and T_{i, 4}, from the patterns under test of the leftmost in FIG. 16. Then, the measurement apparatus 600 shifts sampling clocks by one cycle of symbol cycles so as to count a comparison result signal for symbol transition i that should be used for measuring T_{i, 3} and T_{i, 4}, from the patterns under test of the rightmost in FIG. 16. By using these measurement results, the jitter calculator 690 can calculate T_{i, 3} and T_{i, 4}.

Also, by using the counter section 1410 shown in this figure, the measurement apparatus 600 counts a comparison result signal for symbol transition i that should be used for measuring T_{i, 1}, from the patterns under test of the leftmost in FIG. 17. Then, the measurement apparatus 600 shifts sampling clocks by one cycle of symbol cycles so as to count a comparison result signal for symbol transition i that should be used for measuring T_{i, 2}, from the patterns under test of the rightmost in FIG. 17. By using these measurement results, the jitter calculator 690 can calculate T_{i, 1} and T_{i, 2}.

In this way, the jitter calculator 690 can calculate an EOJ based on a measurement result of the measuring section 680 in the case of shifting sampling clocks by one cycle of symbol cycles, and on a measurement result of the measuring section 680 in the case of not shifting sampling clocks.

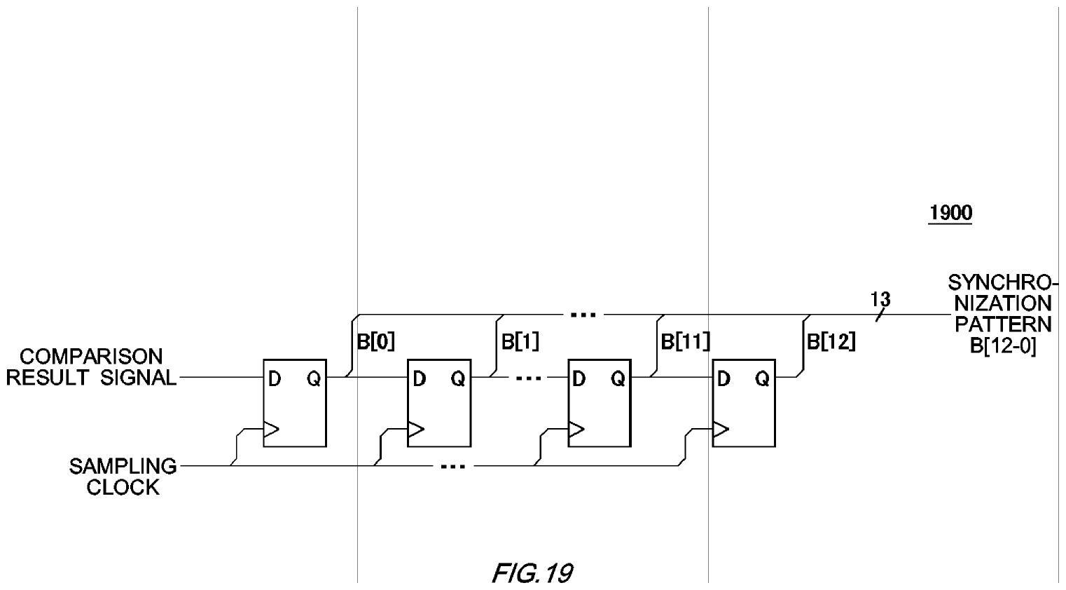

FIG. 19 shows a configuration of a synchronization pattern generator 1900 according to the variant of the present embodiment. In the present variant, the measurement apparatus 600 sets all the symbol transitions to be subject to jitter measurements. Therefore, the measurement apparatus 600 produces a trigger correspondingly to all the symbols subsequently afterwards in response to that sampling patterns match with a reference pattern. The measurement apparatus 600 according to the present variant comprises a synchronization pattern generator 1900 and a trigger producing section 2000, instead of a synchronization pattern producing section 650 and a trigger producing section 660.

The synchronization pattern generator 1900 connects to the clock generator 620 and the sampler 640. The synchronization pattern producing section 650 uses sampling clocks from the clock generator 620 so as to produce synchronization pattern synchronized to sampling patterns according to a predefined sequential number of sampling clocks in patterns under test.

The synchronization pattern generator 1900 includes a shift register composed of a plurality of cascaded D-FFs. The synchronization pattern generator 1900 acquires sampling patterns A[0] to A[12] according to a predefined sequential number of sampling clocks in patterns under test, by continuing to sequentially shift a comparison result signal captured in a shift register according to sampling clocks. In the present embodiment, the synchronization pattern generator 1900 stores 13 symbols worth of comparison result signals, in a similar manner to the sampling pattern acquiring section 1000.

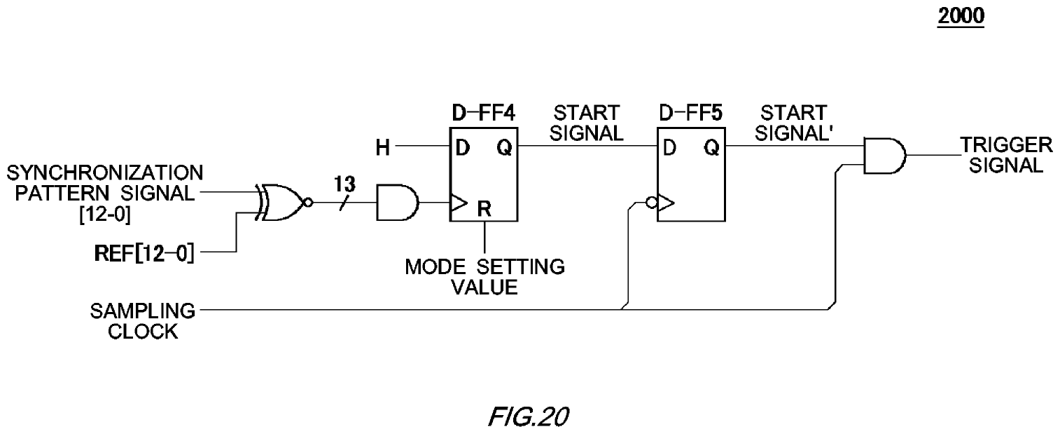

FIG. 20 shows a configuration of a trigger producing section 2000 according to the variant of the present embodiment. The trigger producing section 2000 connects to the clock generator 620 and the synchronization pattern generator 1900. The trigger producing section 2000 produces a trigger at all the sampling clocks subsequently after a time point when a sampling pattern supplied as a synchronization pattern matches with a reference pattern.

The trigger producing section 2000 has a D-FF4, a D-FFS, and a plurality of logic elements. The D-FF4 is similar to the D-FF1 within the trigger producing section 660 shown in FIG. 11, inputs a fixed logic H into a D input, inputs, into a clock input, a signal that rises when a synchronization pattern from the synchronization pattern generator 1900 matches with a reference pattern, and inputs, into a reset input, an inverted value of a mode setting value from the jitter calculator 690. During a training mode in which a mode setting value becomes a logic L, the D-FF4 will be in a reset state and set, to be a logic L, a Q output that will be a start signal. After switching from a training mode to a measurement mode, the D-FF4 sets a start signal to be a logic H in response to that a synchronization pattern B[12-0] matches with a reference pattern corresponding to “REF” in FIG. 5.

The D-FF 5 inputs a start signal from the D-FF4 into a D input, inputs, into a clock input, an inverted value of sampling clocks. The D-FF 5 latches a start signal outputted from the D-FF4 at a time point when sampling clocks are inverted so as to output, from a Q output, a start signal′ indicated in the figure. By taking a logical conjunction of a start signal′ and sampling clocks, an AND gate connected to a Q output of the D-FF 5 produces a trigger at all the sampling clocks subsequently after a time point of a sampling clock after a time when a reference pattern is detected in sampling patterns in a measurement mode.

Furthermore, in the present variant, the threshold generator 670 may allow the shift register 1300 shown in FIG. 13 to store selected values of thresholds for a number of all the symbol worth of patterns under test (8,191 in the present embodiment), so as to generate thresholds of levels according to symbol transitions according to all the sampling clock of patterns under test. The measurement apparatus 600 according to the variant shown above can allow all the symbol transitions in patterns under test that are repeatedly inputted to be subject to jitter measurements.

Various embodiments of the present invention may be described with reference to flowcharts and block diagrams whose blocks may represent (1) steps of processes in which manipulations are performed or (2) sections of apparatuses responsible for performing manipulations. Certain steps and sections may be implemented by dedicated circuitry, programmable circuitry supplied with computer-readable instructions stored on computer-readable media, and/or processors supplied with computer-readable instructions stored on computer-readable media. The dedicated circuitry may include a digital and/or analog hardware circuit, or may include an integrated circuit (IC) and/or a discrete circuit. The programmable circuitry may include a reconfigurable hardware circuit including logical AND, logical OR, logical XOR, logical NAND, logical NOR, and other logical operations, a memory element such as a flip-flop, a register, a field programmable gate array (FPGA) and a programmable logic array (PLA), and the like.

Computer-readable media may include any tangible device that can store instructions to be executed by a suitable device, and as a result, the computer-readable media having the instructions stored thereon comprises an article of manufacture including instructions that can be executed to provide means for performing manipulations specified in the flowcharts or block diagrams. Examples of computer-readable media may include an electronic storage medium, a magnetic storage medium, an optical storage medium, an electromagnetic storage medium, a semiconductor storage medium, and the like. More specific examples of computer-readable media may include a floppy (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disk (DVD), a BLU-RAY (registered trademark) disc, a memory stick, an integrated circuit card, and the like.

Computer-readable instructions may include assembler instructions, instruction-set-architecture (ISA) instructions, machine instructions, machine dependent instructions, microcode, firmware instructions, state-setting data, or either source code or object code described in any combination of one or more programming languages, including an object oriented programming language such as Smalltalk (registered trademark), JAVA (registered trademark) and C++, and a conventional procedural programming language such as a ‘C’ programming language or similar programming languages.

Computer-readable instructions may be provided to a processor or programmable circuitry of a programmable data processing apparatus such as a general purpose computer, special purpose computer, or another computer, locally or via a local area network (LAN), wide area network (WAN) such as the Internet, to execute the computer-readable instructions to create means for performing manipulations specified in the flowcharts or block diagrams. Examples of the processor include a computer processor, a processing unit, a microprocessor, a digital signal processor, a controller, a microcontroller, and the like.

FIG. 21 illustrates an example of a computer 2200 in which a plurality of aspects of the present invention may be embodied in whole or in part. A program that is installed in the computer 2200 can cause the computer 2200 to function as or perform manipulations associated with apparatuses of the embodiments of the present invention or one or more sections thereof, and/or cause the computer 2200 to perform processes of the embodiments of the present invention or steps thereof. Such a program may be executed by the CPU 2212 to cause the computer 2200 to perform certain manipulations associated with some or all of the blocks of flowcharts and block diagrams described herein.

The computer 2200 according to the present embodiment includes a CPU 2212, a RAM 2214, a graphics controller 2216, and a display device 2218, which are mutually connected by a host controller 2210. The computer 2200 also includes input/output units such as a communication interface 2222, a hard disk drive 2224, a DVD-ROM drive 2226 and an IC card drive, which are connected to the host controller 2210 via an input/output controller 2220. The computer also includes legacy input/output units such as a ROM 2230 and a keyboard 2242, which are connected to the input/output controller 2220 through an input/output chip 2240.

The CPU 2212 operates according to programs stored in the ROM 2230 and the RAM 2214, thereby controlling each unit. The graphics controller 2216 obtains image data produced by the CPU 2212 on a frame buffer or the like provided in the RAM 2214 or in itself, and causes the image data to be displayed on the display device 2218.

The communication interface 2222 communicates with other electronic devices via a network. The hard disk drive 2224 stores programs and data used by the CPU 2212 within the computer 2200. The DVD-ROM drive 2226 reads the programs or the data from the DVD-ROM 2201, and provides the hard disk drive 2224 with the programs or the data via the RAM 2214. The IC card drive reads programs and data from an IC card, and/or writes programs and data into the IC card.

The ROM 2230 stores therein a rise program or the like executed by the computer 2200 at the time of activation, and/or a program depending on the hardware of the computer 2200. The input/output chip 2240 may also connect various input/output units via a parallel port, a serial port, a keyboard port, a mouse port, or the like to the input/output controller 2220.

A program is provided by computer-readable media such as the DVD-ROM 2201 or the IC card. The program is read from the computer-readable media, installed into the hard disk drive 2224, RAM 2214, or ROM 2230, which are also examples of computer-readable media, and executed by the CPU 2212. The information processing described in these programs is read into the computer 2200, resulting in cooperation between a program and the above-described various types of hardware resources. An apparatus or method may be constituted by realizing the manipulation or processing of information in accordance with the usage of the computer 2200.

For example, when communication is performed between the computer 2200 and an external device, the CPU 2212 may execute a communication program loaded onto the RAM 2214 to instruct communication processing to the communication interface 2222, based on the processing described in the communication program. The communication interface 2222, under control of the CPU 2212, reads transmission data stored on a transmission buffering region provided in a recording medium such as the RAM 2214, the hard disk drive 2224, the DVD-ROM 2201, or the IC card, and transmits the read transmission data to a network or writes reception data received from a network to a reception buffering region or the like provided on the recording medium.

In addition, the CPU 2212 may cause all or a necessary portion of a file or a database to be read into the RAM 2214, the file or the database having been stored in an external recording medium such as the hard disk drive 2224, the DVD-ROM drive 2226 (DVD-ROM 2201), the IC card, etc. and perform various types of processes on data on the RAM 2214. The CPU 2212 may then write back the processed data to the external recording medium.

Various types of information, such as various types of programs, data, tables, and databases, may be stored in the recording medium and may be subjected to information processing. The CPU 2212 may perform various types of processing on the data read from the RAM 2214, which includes various types of manipulations, processing of information, condition judging, conditional branch, unconditional branch, search/replace of information, etc., as described throughout this disclosure and designated by an instruction sequence of programs, and writes the result back to the RAM 2214. In addition, the CPU 2212 may search for information in a file, a database, etc., in the recording medium. For example, when a plurality of entries, each having an attribute value of a first attribute associated with an attribute value of a second attribute, are stored in the recording medium, the CPU 2212 may search for an entry matching the condition whose attribute value of the first attribute is designated, from among the plurality of entries, and read the attribute value of the second attribute stored in the entry, thereby obtaining the attribute value of the second attribute associated with the first attribute satisfying the predefined condition.

The above-explained program or software modules may be stored in the computer-readable media on or near the computer 2200. In addition, a recording medium such as a hard disk or a RAM provided in a server system connected to a dedicated communication network or the Internet can be used as the computer-readable media, thereby providing the program to the computer 2200 via the network.

While the embodiments of the present invention have been described, the technical scope of the invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCE NUMBERS

100 DUT, 110 PRBS generator, 120 PRBS generator, 130 Mapping section, 140 Encoder, 600 Measurement apparatus, 620 Clock generator, 640 Sampler, 650 Synchronization pattern producing section, 660 Trigger producing section, 670 Threshold generator, 680 Measuring section, 690 Jitter calculator, 700 Shifter, 710 Half divider, 720 Selector, 730 Divider, 740 Variable delay circuit, 910 Comparator, 920 D-FF, 1000 Sampling pattern acquiring section, 1010 Pseudo-random pattern generator, 1020 Pattern synchronizer, 1030 AND gate, 1040 Matching detection circuit, 1050 OR gate, 1300 Shift register, 1310 Selector, 1320 Selector, 1330 DAC, 1400 Counter selector, 1410-0 to 1410-11 Counter section, 1420 Counter section, 1430 Count stop detector, 1810 Interleaver, 1820-0 to 1820-2 Counter, 1830 Adder, 1900 Synchronization pattern generator, 2000 Trigger producing section, 2200 Computer, 2201 DVD-ROM, 2210 Host controller, 2212 CPU, 2214 RAM, 2216 Graphics controller, 2218 Display device, 2220 Input/output controller, 2222 Communication interface, 2224 Hard disk drive, 2226 DVD-ROM drive, 2230 ROM, 2240 Input/output chip, 2242 Keyboard

What is claimed is:

1. A measurement apparatus comprising:
a clock generator configured to generate a sampling clock having a longer sampling cycle than a symbol cycle in a pattern under test including a symbol with a predefined number of symbols;
a sampler configured to sample, according to the sampling clock, the pattern under test that is repeatedly inputted; and
a measuring section configured to measure a sampling result of the sampler according to the sampling clock of a time point corresponding to a symbol transition that becomes subject to jitter measurements in the pattern under test that is repeatedly inputted.

2. The measurement apparatus according to claim 1, wherein the sampling cycle has a cycle of an integer multiple of two or more times the symbol cycles.

3. The measurement apparatus according to claim 2,
wherein the sampling cycle has a cycle of a first integer multiple times the symbol cycle, and
wherein the first integer and the predefined number of symbols are coprime with each other.

4. The measurement apparatus according to claim 1, wherein the clock generator has a divider configured to divide clock signals that sets the symbol cycle as one cycle so as to produce the sampling clocks.

5. The measurement apparatus according to claim 2, wherein the clock generator has a divider configured to divide clock signals that sets the symbol cycle as one cycle so as to produce the sampling clocks.

6. The measurement apparatus according to claim 3, wherein the clock generator has a divider configured to divide clock signals that sets the symbol cycle as one cycle so as to produce the sampling clocks.

7. The measurement apparatus according to claim 4, wherein the clock generator has a shifter that is able to switch whether or not to shift the sampling clocks by one cycle of the symbol cycles.

8. The measurement apparatus according to claim 7, further comprising a jitter calculator configured to calculate an EOJ (even-odd jitter) based on a measurement result of the measuring section in a case of shifting the sampling clocks by one cycle of the symbol cycles, and on a measurement result of the measuring section in a case of not shifting the sampling clocks.

9. The measurement apparatus according to claim 1, further comprising
a trigger producing section configured to produce a trigger to the inputted pattern under test at a time point when a predefined symbol pattern is generated,
wherein the measuring section measures the sampling result in response to the trigger.

10. The measurement apparatus according to claim 2, further comprising
a trigger producing section configured to produce a trigger to the inputted pattern under test at a time point when a predefined symbol pattern is generated,
wherein the measuring section measures the sampling result in response to the trigger.

11. The measurement apparatus according to claim 3, further comprising
a trigger producing section configured to produce a trigger to the inputted pattern under test at a time point when a predefined symbol pattern is generated,
wherein the measuring section measures the sampling result in response to the trigger.

12. The measurement apparatus according to claim 4, further comprising
a trigger producing section configured to produce a trigger to the inputted pattern under test at a time point when a predefined symbol pattern is generated,
wherein the measuring section measures the sampling result in response to the trigger.

13. The measurement apparatus according to claim 9, wherein the trigger producing section produces the trigger in response to that a sampling pattern according to a predefined sequential number of sampling clocks in the patterns under test matches with a predefined comparison patterns.

14. The measurement apparatus according to claim 13, wherein the trigger producing section produces the trigger in response to that the sampling pattern matches with any of a plurality of comparison patterns.

15. The measurement apparatus according to claim 13, further comprising
a synchronization pattern producing section configured to produce synchronization pattern synchronized to the sampling patterns in the patterns under test,
wherein the trigger producing section produces the trigger in response to that the synchronization pattern matches with the comparison patterns.

16. The measurement apparatus according to claim 14, further comprising
a synchronization pattern producing section configured to produce synchronization pattern synchronized to the sampling patterns in the patterns under test,
wherein the trigger producing section produces the trigger in response to that the synchronization pattern matches with the comparison patterns.

17. The measurement apparatus according to claim 15, wherein the synchronization pattern producing section has:
a pseudo-random pattern generator configured to generate a same pseudo-random pattern as a pattern that results from extracting, with sampling clocks, a pseudo-random pattern used for generating the patterns under test,
a pattern synchronizer configured to synchronize a pseudo-random pattern generated by the pseudo-random pattern generator with a pattern extracted, from the patterns under test, according to a predefined sequential number of sampling clocks.

18. The measurement apparatus according to claim 17,
wherein the patterns under test includes a symbol of a multi-value signal having three or more levels,
wherein the measurement apparatus further comprises a threshold generator configured to generate a threshold of level according to a symbol transition that is subject to jitter measurements,
wherein the sampler is configured to sample the patterns under test by using the threshold.

19. The measurement apparatus according to claim 18, wherein the threshold generator generates a threshold for extracting, from the patterns under test, a pseudo-random pattern used for generating the patterns under test, in a training mode that synchronizes a pseudo-random pattern generated by the pseudo-random pattern generator with a pseudo-random pattern extracted from the patterns under test.

20. A measurement method, comprising:
generating, by a measurement apparatus, a sampling clock having a longer sampling cycle than a symbol cycle in a pattern under test including a symbol with a predefined number of symbols;
sampling, by a measurement apparatus, according to the sampling clock, the pattern under test that is repeatedly inputted; and
measuring, by a measurement apparatus, a sampling result of the pattern under testaccording to the sampling clock of a time point corresponding to a symbol transition that becomes subject to jitter measurements in the pattern under test that is repeatedly inputted.
